(19) United States
(12) Patent Application Publication
(10) Pub. No.: US 2026/0324402 A1
(43) Pub. Date: Oct. 15, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Wei-Jen CHANG, Miaoli County (TW); Jheng-Yi JIANG, Hsinchu City (TW); Ruei-Jyun HSU, Hsinchu City (TW); Chia-Chi HO, Zhudong Township (TW); Chung-Shih CHIANG, Zhubei City (TW)

(73) Assignee: Taiwan Semiconductor Manufacturing Company, Ltd., Hsinchu (TW)

(21) Appl. No.: 19/174,590

(22) Filed: Apr. 9, 2025

(51) Int. Cl. H10W 20/41; H10D 30/01; H10D 30/47; H10D 62/824; H10D 64/01; H10D 64/23; H10W 20/20

(52) U.S. Cl. CPC H10W 20/435; H10D 30/015; H10D 30/475; H10D 62/824; H10D 64/0117; H10D 64/256; H10D 64/258; H10W 20/2134

(57) ABSTRACT

A semiconductor transistor device includes gate electrodes on a first side (e.g., frontside) of the device and source/drain electrodes disposed in recesses formed from a second side (e.g., backside) of the device. The recesses are formed from the backside of the device through a substrate and into a gallium-based layer. The recesses are filled with conductive (e.g., metal) material to form the source/drain electrodes. The source/drain electrodes may be formed in part of the gallium-based layer. The source/drain electrodes may be connected to a backside ground plate, which may provide a connection to ground and may also dissipate heat. Transistor devices with backside source/drain electrodes may have a reduced width since source/drain electrodes formed on opposite sides from gate electrodes may be formed at reduced lateral distances from the gate electrodes. The reduced width may reduce voltage drop and heat generation, leading to increased electron-mobility and lower serial resistance.

### BACKGROUND

Gallium-based materials offer several advantageous electrical properties, mechanical properties, and chemical properties over other types of semiconductor materials, such as a wide band gap, a high breakdown voltage, a high electron mobility, a large elastic modulus, high piezoelectric and piezoresistive coefficients, and chemical inertness. Such advantages make gallium-based materials attractive for making semiconductor devices such as power management devices, high brightness light-emitting diodes (LEDs), and other types of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example implementation of a gallium-based semiconductor device described herein.

FIGS. 2A-2H are diagrams of an example implementation of forming a gallium-based semiconductor device described herein.

FIG. 3 is a diagram of an example implementation of a gallium-based semiconductor device described herein.

FIGS. 4A-4I are diagrams of an example implementation of forming a gallium-based semiconductor device described herein.

FIG. 5 is a diagram of an example implementation of a gallium-based semiconductor device described herein.

FIGS. 6A-6E are diagrams of an example implementation of forming a gallium-based semiconductor device described herein.

FIGS. 7A-7C are diagrams of example implementations of a gallium-based semiconductor device described herein.

FIG. 8 is a flowchart of an example process associated with forming a gallium-based semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a transistor, such as, for example, a field-effect transistor (FET), a fin field-effect transistor (finFET), a high-electron-mobility transistor (HEMT), and/or other type of transistor, a gate structure may be formed on a first side (e.g., frontside) of a substrate, and source/drain regions may be formed on the first side of the substrate on lateral sides of the gate structure. Contacts to source/drain regions and corresponding metallization layers (e.g., M1/M2 layers) may be formed over and/or on the source/drain regions on the first side of the substrate.

In power switching circuit applications, in order to reduce on-resistance (Rₒₙ), a device may have a large width (e.g., hundreds of source/drain region and gate structure (finger) combinations). For example, a single finger width may be approximately 50 μm to approximately 1000 μm. However, long metallization level paths for source/drain connections caused by the large width semiconductor transistor device may result in a voltage (e.g., IR) drop for the device. In addition, large width semiconductor transistor devices may exhibit increases in heat generation without corresponding structures to dissipate heat, leading to lower electron mobility and higher serial resistance, which may reduce device reliability and performance.

In some implementations described herein, a semiconductor transistor device includes gate electrodes on a first side (e.g., frontside) of the device and some source/drain electrodes disposed in recesses formed from a second side (e.g., backside) of the device. The recesses are formed from the backside of the device through a substrate and into a gallium-based layer (e.g., a gallium nitride (GaN) layer). The recesses are filled with conductive (e.g., metal) material to form the source/drain electrodes. The source/drain electrodes may be formed in part of the gallium-based layer. The source/drain electrodes may be connected to a backside ground plate formed under the substrate. The ground plate may provide a connection to ground for the source/drain electrodes and may also dissipate heat. A voltage connection to the source/drain electrodes may be made by a through-gallium-via (TGV) from a voltage source on a frontside of the semiconductor device. Transistor devices with backside source/drain electrodes may reduce the width of the transistor devices since source/drain electrodes formed on opposite sides from gate electrodes may be formed at reduced lateral distances from the gate electrodes in comparison to source/drain electrodes formed on a same side as the gate electrodes. The reduced width may reduce voltage drop and heat generation. In addition, backside ground plates may be used to dissipate heat, leading to increased electron-mobility and lower serial resistance, which may increase device reliability and performance.

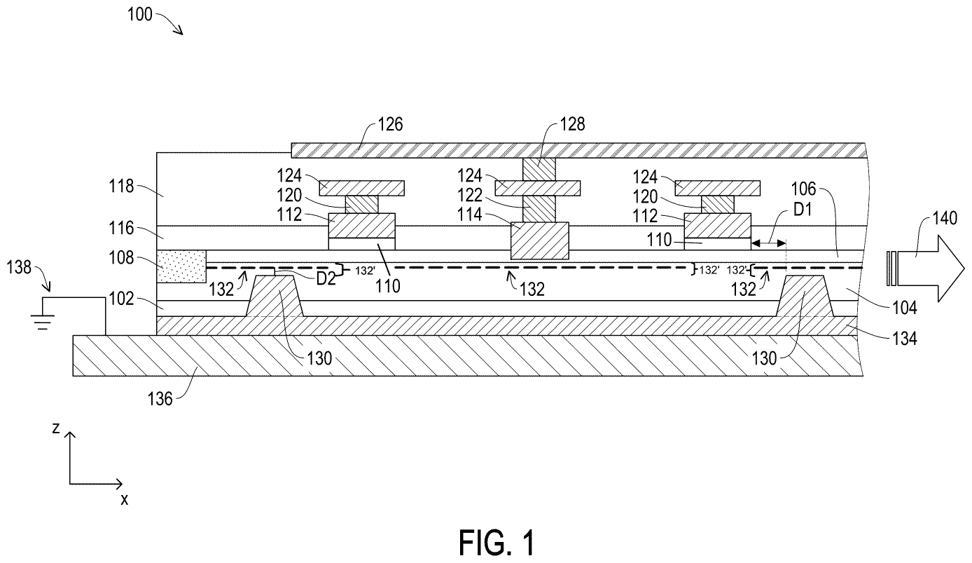

FIG. 1 is a diagram of an example implementation of a semiconductor device 100 (e.g., a gallium nitride (GaN)-based semiconductor device) described herein. In some implementations, the semiconductor device 100 may include a gallium-based transistor, such as GaN-based HEMT. However, other types of transistor structures (e.g., FETs, finFETs, etc.) are within the scope of the present disclosure.

GaN-based HEMTs are HEMTs that are formed on a GaN substrate. GaN-based HEMTs may offer high operating voltages (e.g., 12 volts to 1200 volts or greater) and high frequency switching speeds for radar, power switching, and millimeter wave communications, among other examples. A GaN-based HEMT may be formed on a GaN layer, which is formed on a silicon, sapphire, or silicon carbine substrate. An aluminum gallium nitride (AlGaN) layer may be formed on the GaN layer. The GaN layer may be undoped and have a different bandgap from the AlGaN layer. Because the AlGaN layer has a different bandgap than the GaN layer, the GaN and AlGaN layers may form a heterojunction structure for the GaN-based HEMT. For example, a portion of the GaN layer may function as a channel layer with a first bandgap, and the AlGaN may function as a barrier layer with a second bandgap that is different from the first bandgap. In more detail, a two-dimensional electron gas (2DEG) channel region may be formed in the GaN layer. The 2DEG channel region is a region of high electron mobility between the GaN layer and the AlGaN layer. In the case of GaN HEMTs, electrons generated in the AlGaN layer move into the GaN layer to form a depleted AlGaN layer. This is due to a heterojunction created by different band-gap materials of the GaN layer and the AlGaN layer, which forms a quantum well in a conduction band in the GaN layer. The electrons in the conduction band are trapped and can move quickly without colliding with impurities in the GaN layer because the GaN layer is undoped. As a result, the 2DEG channel region with a high concentration of highly mobile conducting electrons are created.

As shown in FIG. 1, the semiconductor device 100 includes a substrate 102. The substrate 102 may correspond to a portion of a semiconductor wafer on which the semiconductor device 100 is formed. The substrate 102 includes a silicon (Si) substrate, a substrate formed of a material including silicon, a sapphire substrate, a silicon on insulator (SOI) substrate, or another type of semiconductor substrate. The substrate 102 may extend in an x-direction in the semiconductor device 100.

A first heterojunction layer 104 is formed on the substrate 102 in a z-direction in the semiconductor device 100. The first heterojunction layer 104 (e.g., a buffer layer) may be formed from undoped GaN, and may be epitaxially grown from a seed layer. A deposition tool may be used to deposit the material of the first heterojunction layer 104. The first heterojunction layer 104 may function as a carrier electron layer for the semiconductor device 100 (e.g., a GaN-based semiconductor device). The semiconductor device 100 may include a second heterojunction layer 106 (e.g., a barrier layer) that may include aluminum gallium nitride (AlGaN) and/or another suitable material. The second heterojunction layer 106 is formed on the first heterojunction layer 104 in a z-direction in the semiconductor device 100. The second heterojunction layer 106 may have a different bandgap and lattice structure from a bandgap and lattice structure of the first heterojunction layer 104, so that the first heterojunction layer 104 and the second heterojunction layer 106 may form a heterojunction structure for a gallium-nitride-based semiconductor device. As a result, there may be a lattice mismatch between the first heterojunction layer 104 and the second heterojunction layer 106. For example, the lattice mismatch between the first heterojunction layer 104 and the second heterojunction layer 106 may be included in the range of approximately 0.1% to approximately 5%. However, other values and/or ranges for the lattice mismatch percentage are within the scope of the present disclosure. In some implementations, the first heterojunction layer 104 may include gallium arsenide (GaAs) and the second heterojunction layer 106 may include aluminum gallium arsenide (AlGaAs).

As further shown in FIG. 1, the semiconductor device 100 may include one or more isolation regions 108 (e.g., doped implant regions) formed in the second heterojunction layer 106 and the first heterojunction layer 104. In some implementations, an isolation region 108 is formed by an ion implantation process, and may be formed through the second heterojunction layer 106, and in a portion (e.g., upper portion) of the first heterojunction layer 104. Alternatively, in some implementations, an isolation region 108 may include a shallow trench isolation (STI) region. An STI region may include dielectric material such as a silicon oxide (SiOₓ), a silicon nitride (SiₓN_{y}), a silicon oxynitride (SiON), fluoride-doped silicate glass (FSG), a low dielectric constant (low-k) dielectric material, and/or another suitable insulating material. An isolation region 108 may extend through the second heterojunction layer 106 into the first heterojunction layer 104.

Additionally, a plurality of gate electrodes 112 (also referred to as “gates”) may be formed over the heterojunction structure including the first heterojunction layer 104 and the second heterojunction layer 106 in the z-direction in the semiconductor device 100. A gate electrode 112 may be disposed on a gate separation layer 110 in the z-direction in the semiconductor device 100. The gate separation layer 110 is disposed between the gate electrode 112 and the second heterojunction layer 106. In some implementations, the gate separation layer 110 includes an insulator. Alternatively, the gate separation layer 110 includes a doped III-V material, such as p-doped gallium nitride (GaN) for an enhanced HEMT, or an n-doped gallium nitride (GaN) for a depleted HEMT. The doped material may pull electrons from the channel or may donate holes to the channel under the gate electrode 112 in order to form a broken channel (e.g., when the gallium-nitride-based electronic structure is a normally off or an enhancement mode (e-mode) III-N HEMT device). In some implementations, the gate separation layer 110 may be omitted, such as for a normally on or a depletion mode (d-mode) III-N HEMT device.

A gate electrode 112 may be disposed adjacent one or more source/drain electrodes 114. “Source/drain electrode” may refer to a source electrode or a drain electrode, individually or collectively, dependent upon the context. The source/drain electrode 114 is disposed on the second heterojunction layer 106, with a portion of the source/drain electrode 114 disposed in the second heterojunction layer 106. Alternatively, the source/drain electrode 114 is on a top surface of the second heterojunction layer 106, without being in the second heterojunction layer 106. The gate electrode 112 and the source/drain electrode 114 may include one or more conductive materials (e.g., metals) such as titanium, aluminum, nickel, and/or gold, among other examples, or a polycrystalline material (e.g., polycrystalline silicon).

A dielectric layer 116 is disposed on the second heterojunction layer 106 and around sides of the gate separation layer 110, the gate electrodes 112, and the source/drain electrode 114. The dielectric layer 116 may include an oxide (e.g., a silicon oxide (SiOₓ) and/or another oxide material), and/or another suitable dielectric material. An inter-metal dielectric (IMD) layer 118 is formed on the dielectric layer 116. The IMD layer 118 may include an undoped silicate glass (USG), a boron-containing silicate glass (BSG), a fluorine-containing silicate glass (FSG), tetraethyl orthosilicate (TEOS), hydrogen silsesquioxane (HSQ), a silicon nitride (SiₓN_{y}), silicon carbide (SiC), silicon oxynitride (SiON), and/or another suitable dielectric material.

The IMD layer 118 may include a plurality of conductive structures such as, for example, gate contacts 120, source/drain contacts 122, first metallization structures 124, second metallization structures 126, and interconnect structures 128. One or more of the conductive structures are electrically coupled and/or physically coupled to one or more of the gate electrodes 112 and/or source/drain electrodes 114. The conductive structures provide electrical routing that enables signals and/or power to be provided to and/or from the gate electrodes 112 and/or source/drain electrodes 114. The conductive structures may include a combination of vias, trenches, contacts, plugs, interconnects, metallization layers, conductive traces, and/or other types of conductive structures. The conductive structures may be one or more electrically conductive materials such as tungsten (W), cobalt (Co), ruthenium (Ru), titanium (Ti), aluminum (Al), copper (Cu), aluminum copper (AlCu), gold (Au), nickel (Ni), and/or a combination thereof, among other examples of electrically conductive materials. In some implementations, one or more liner layers are included between the conductive structures and the IMD layers 118. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures may be arranged in in a vertical manner (e.g., in the z-direction). The plurality of stacked conductive structures may be referred to as metallization layers (M-layers). For example, a metal-1 (M1) layer including first metallization structures 124 may be directly coupled to the gate contacts 120 and/or the source/drain contacts 122, and a metal-2 layer (M2) layer may be located above the M1 layer in and/or on the IMD layer 118, a metal-2 layer (M2) layer including second metallization structures 126 may be located above the M1 layer, and so on. Additionally, via layers may be included between vertically arranged M-layers. For example, a via-1 (V1) layer including interconnect structures 128 may be included between the M1 layer and the M2 layer to interconnect the M1 layer and the M2 layer.

The semiconductor device 100 may have a frontside and a backside. As used herein, “frontside” may refer to a side of the semiconductor device 100 over a top side of the substrate 102 and/or over a top side of the first heterojunction layer 104 in the z-direction. The frontside of the semiconductor device 100 may also be referred to herein as a “first side” of the semiconductor device 100. As used herein, “backside” may refer to a side of the semiconductor device 100 under a bottom side of the substrate 102 and/or under a bottom side of the first heterojunction layer 104 in the z-direction. The backside of the semiconductor device 100 is opposite the frontside of the semiconductor device 100. The backside of the semiconductor device 100 may also be referred to herein as a “second side” of the semiconductor device 100.

The gate electrodes 112, the source/drain electrode 114, the gate contacts 120, the source/drain contacts 122, the first metallization structures 124, the second metallization structures 126, and the interconnect structures 128 are on a frontside of the semiconductor device 100. Source/drain electrodes 130 extend from a backside of the semiconductor device 100 through the substrate 102 and through the bottom side of the first heterojunction layer 104 into the first heterojunction layer 104. The source/drain electrodes 130 are spaced apart from the second heterojunction layer 106. A portion of the first heterojunction layer 104 occupies a space between an edge of each source/drain electrode 130 and the second heterojunction layer 106.

The portions of the first heterojunction layer 104 between the edges of the source/drain electrodes 130 and the second heterojunction layer 106 include 2DEG channel regions 132. The 2DEG channel regions 132 are regions of high electron mobility between the first heterojunction layer 104 (e.g., GaN layer) and the second heterojunction layer 106 (e.g., AlGaN layer). In some implementations, the 2DEG channel regions 132 are adjacent to an interface between the first heterojunction layer 104 and the second heterojunction layer 106. In the case of GaN HEMTs, electrons generated in the second heterojunction layer 106 (e.g., AlGaN layer) move into the first heterojunction layer 104 (e.g., GaN layer) to form a depleted second heterojunction layer 106. This is due to a heterojunction created by different band-gap materials of the first heterojunction layer 104 and the second heterojunction layer 106, which forms a quantum well in a conduction band in the first heterojunction layer 104. The electrons in the conduction band are trapped and can move quickly without colliding with impurities in the first heterojunction layer 104 because the first heterojunction layer 104 is undoped. As a result, 2DEG channel regions 132 of an HEMT are created. The 2DEG channel regions 132 have a high concentration of highly mobile conducting electrons. The source/drain electrode 114 and the source/drain electrodes 130 are connected to (e.g., form an ohmic contact with) the 2DEG channel regions 132. In some implementations, the source/drain electrode 114 and the source/drain electrodes 130 are connected to the 2DEG channel regions 132 even though the source/drain electrode 114 and the source/drain electrodes 130 are spaced apart from and are not in direct physical contact with the 2DEG channel regions 132. The source/drain electrode 114 and the source/drain electrodes 130 form ohmic contacts with the 2DEG channel regions 132 from different sides of the 2DEG channel regions 132. In some implementations, a dimension D2 in the z-direction between an edge of a source/drain electrode 130 and the 2DEG channel region 132 is included in the range of approximately 1 nanometer to smaller than 5 nanometers.

In some implementations, a thickness of the first heterojunction layer 104 in the z-direction is included in a range of approximately 1 micron to approximately 10 microns. A thickness in the specified range may ensure an even and smooth interface between the first heterojunction layer 104 and the second heterojunction layer 106 to provide for the formation of the 2DEG channel regions 132 having high electron mobility. However, other values for the thickness of the first heterojunction layer 104 are within the scope of this disclosure.

In some implementations, a thickness of the second heterojunction layer 106 in the z-direction is included in a range of approximately 3 angstroms to approximately 200 angstroms. However, other values for the thickness of the second heterojunction layer 106 are within the scope of this disclosure.

In some implementations, a misfit dislocation region 132′ (e.g., lattice mismatch layer) may be adjacent to the interface between the first heterojunction layer 104 and the second heterojunction layer 106. The misfit dislocation region 132′ may be in the first heterojunction layer 104 in a space between a source/drain electrode 130 and the second heterojunction layer 106. The 2DEG channel regions 132 may include and/or overlap with misfit dislocation regions 132′. A misfit dislocation region 132′ (e.g., lattice mismatch layer) may include one or more crystal defects at and/or adjacent to the interface between the first heterojunction layer 104 and the second heterojunction layer 106.

A conductive layer 134 is on the backside of the semiconductor device 100 under the bottom side of the substrate 102, and a ground plate 136 is disposed under the conductive layer 134 on the backside of the semiconductor device 100. The source/drain electrodes 130 are electrically connected to the ground plate 136 through the conductive layer 134. In some implementations, the source/drain electrodes 130, the conductive layer 134, and the ground plate 136 include one or more electrically conductive materials such as tungsten (W), cobalt (Co), ruthenium (Ru), titanium (Ti), aluminum (Al), copper (Cu), aluminum copper (AlCu), gold (Au), nickel (Ni), and/or a combination thereof, among other examples of electrically conductive materials. In some implementations, the source/drain electrodes 130, the conductive layer 134, and the ground plate 136 include one or more liner layers such as barrier liners, adhesion liners, and/or another type of liners. Examples of materials for the one or more liners include tantalum nitride (TaN) and/or titanium nitride (TiN), among other examples.

The ground plate 136 is a conductive plate that provides a ground voltage connection 138 to the source/drain electrodes 130 through the conductive layer 134. In addition to providing an electrical path to ground for the source/drain electrodes 130, the ground plate 136 functions to dissipate heat generated by HEMT devices during operation. The heat dissipation decreases channel layer (e.g., 2DEG channel regions 132) temperature to enable increased electron-mobility and lower serial resistance, which may increase device reliability and performance.

The formation of the source/drain electrodes 130 from a backside of the semiconductor device 100, and their resulting position through the substrate 102 and through the bottom side of the first heterojunction layer 104 into the first heterojunction layer 104, permits closer spacing of the source/drain electrodes 130 to gate structures (e.g., gate electrodes 112 and gate separation layers 110) than if the source/drain electrodes 130 were formed from a frontside of the semiconductor device 100 (e.g., similar to source/drain electrode 114).

In some implementations, an x-direction distance (e.g., spacing) between a gate structure (e.g., gate electrode 112 and/or gate separation layer 110) and an edge of a source/drain electrode 130 (indicated in FIG. 1 as a dimension D1) is included in a range of approximately 1 micron to approximately 5 microns. If the dimension D1 is less than approximately 1 micron, channel control of the gate will be reduced and an increase in drain-induced barrier lowering (DIBL) will occur. A dimension D1 greater than approximately 5 microns may result in long metallization level paths for source/drain connections, which may cause a voltage (e.g., IR) drop for devices using the GaN-based HEMTs. In addition, if the dimension D1 is greater than approximately 5 microns, the GaN-based HEMTs may have larger source serial resistance, and the lateral size of the GaN-based HEMTs may increase, thereby reducing device density in the semiconductor device and increasing chip area. However, other values and/or ranges for the x-direction distance between a gate structure (e.g., gate electrode 112 and/or gate separation layer 110) and an edge of a source/drain electrode 130 are within the scope of the present disclosure.

The arrow 140 in FIG. 1 indicates that the semiconductor device 100 (e.g., HEMT device) includes multiple fingers (e.g., hundreds of fingers), where a “finger” as shown in FIG. 1 includes a transistor structure including gate electrodes 112, a source/drain electrode 114 between the gate electrodes 112, and source/drain electrodes 130 adjacent to respective gate electrodes 112.

As indicated above, FIG. 1 is provided as an example. Other examples may differ from what is described with regard to FIG. 1.

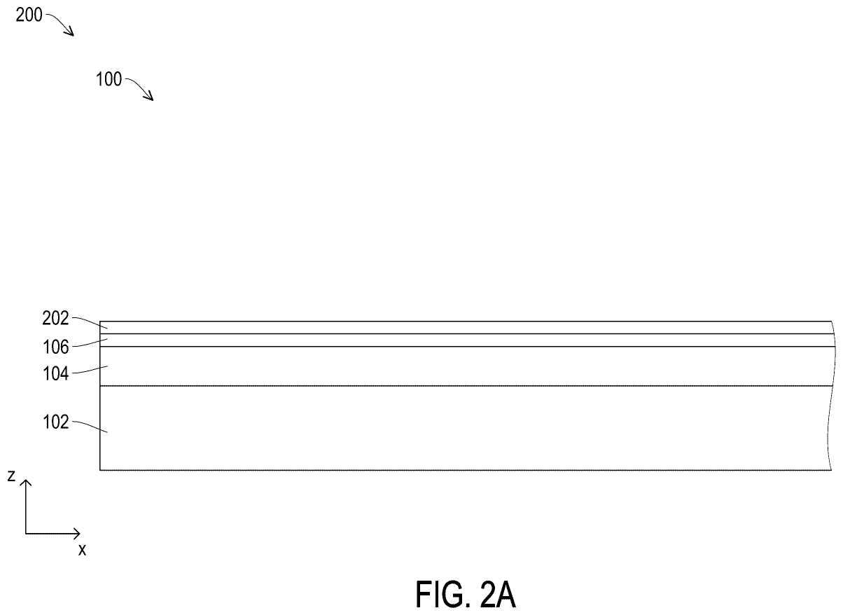

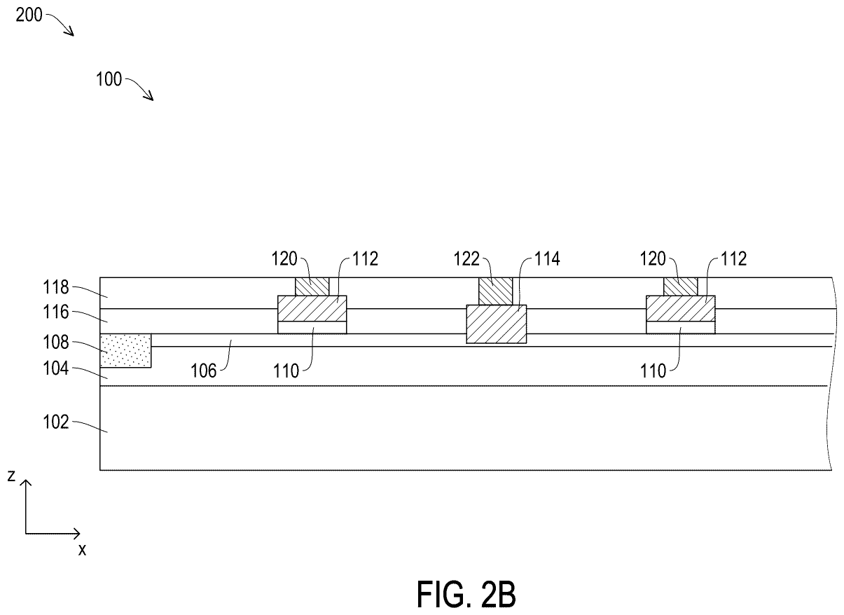

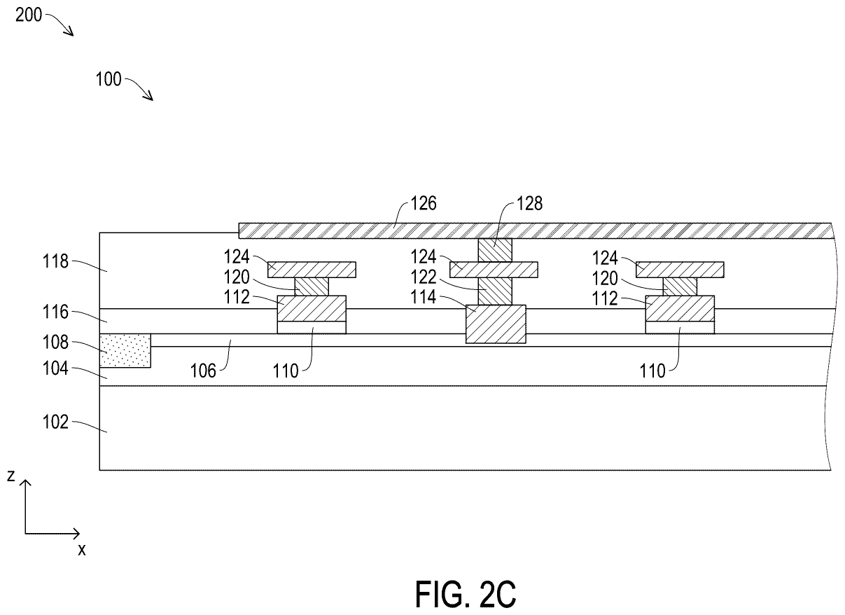

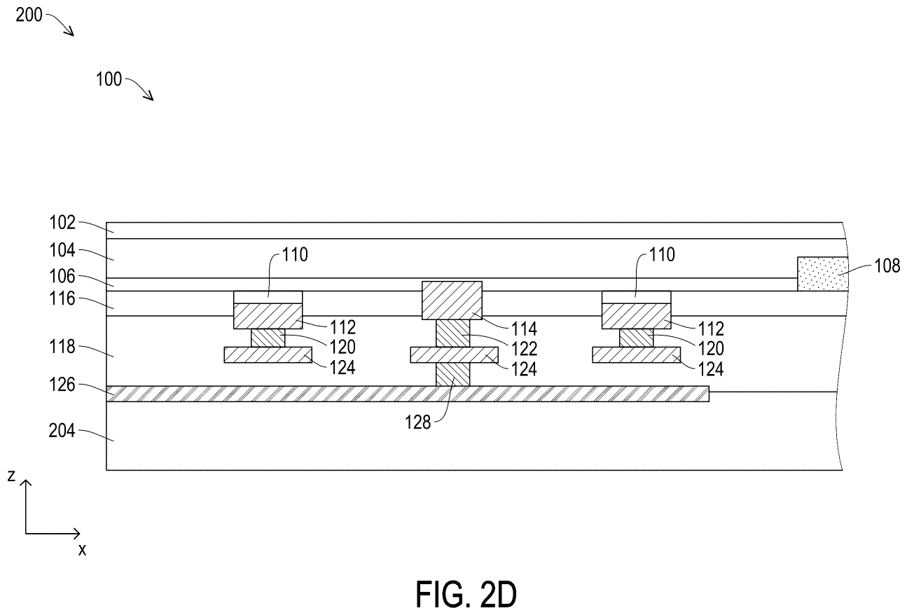

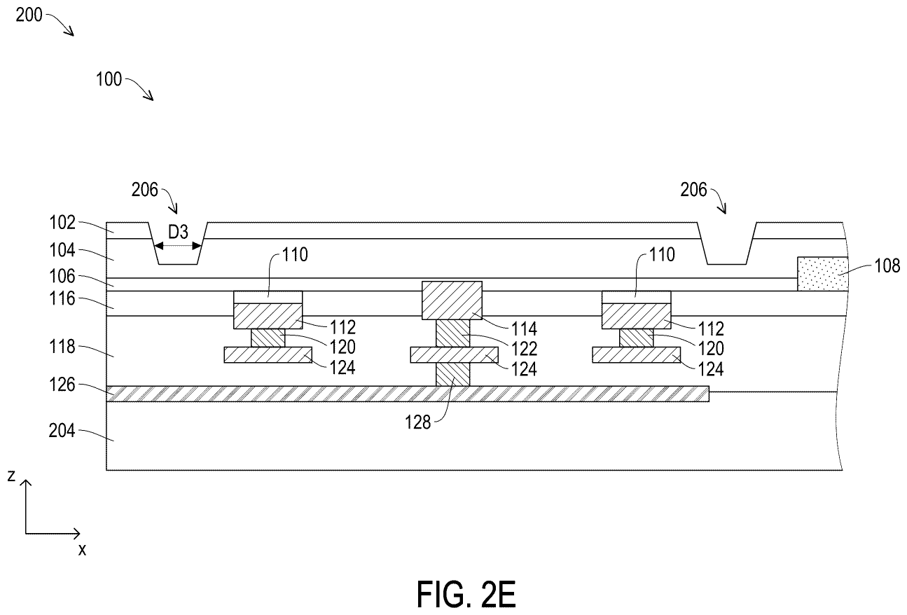

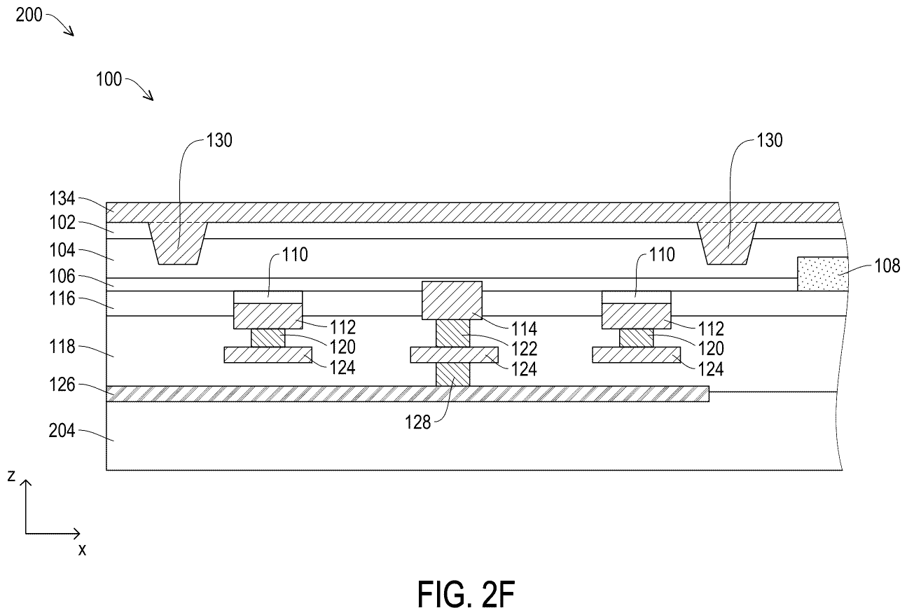

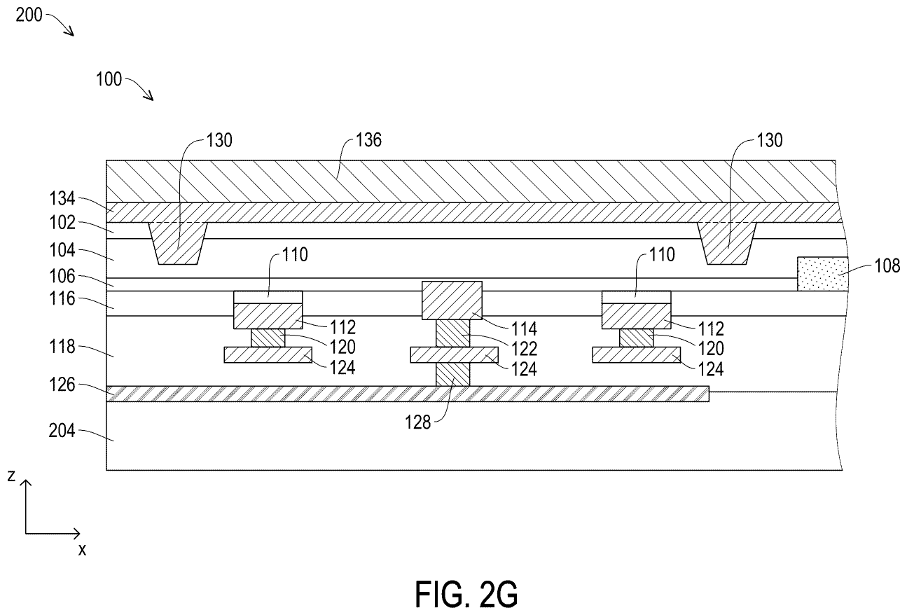

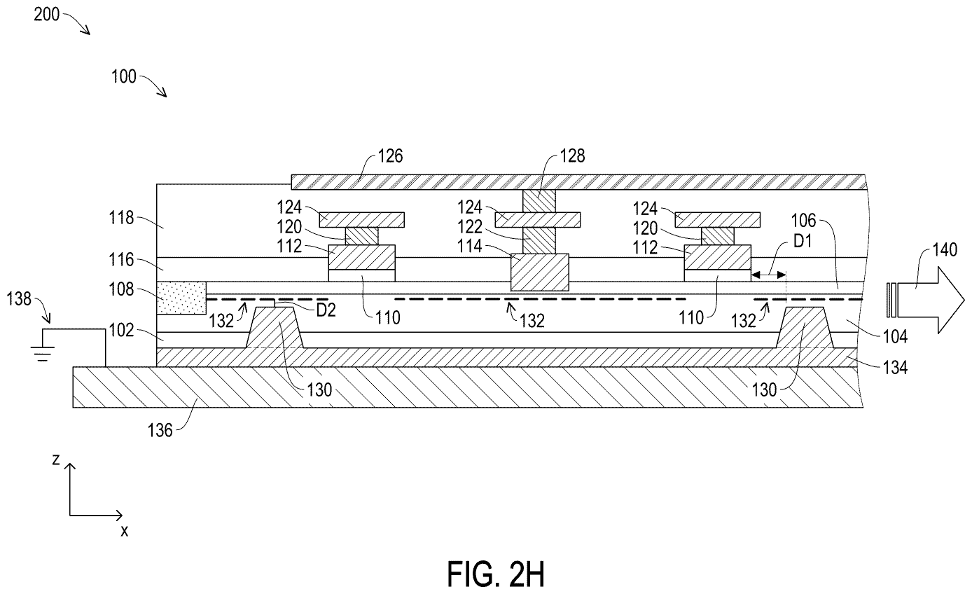

FIGS. 2A-2H are diagrams of an example implementation 200 of forming a gallium-based semiconductor device described herein. The semiconductor device 100 (e.g., a GaN-based semiconductor device) may include a GaN-based HEMT, a GaN-based light emitting diode (LED), a GaN-based high-voltage device (e.g., device that is configured to operate at voltages of approximately 12 volts or greater), and/or another type of GaN-based semiconductor device.

One or more semiconductor processing tools may be used to form one or more portions of the semiconductor device 100. In some implementations, forming the semiconductor device 100 may include using a deposition tool to deposit one or more layers and/or structures. In some implementations, forming the semiconductor device 100 may include using an exposure tool to expose photoresist layers to form patterns in the photoresist layers, and using an etch tool to etch one or more other layers to form one or more structures of the semiconductor device 100. As another example, a planarization tool may be used to planarize portions of the semiconductor device 100. As another example, a plating tool may be used to deposit metal structures and/or layers of the semiconductor device 100. An example semiconductor device 100 is illustrated and described in connection with FIG. 1.

As shown in FIG. 2A, a substrate 102 is provided. The first heterojunction layer 104 (e.g., a GaN layer) is deposited on the substrate 102, the second heterojunction layer 106 (e.g., an AlGaN layer) is deposited on the first heterojunction layer 104, and a blanket gate separation layer 202 is deposited on the second heterojunction layer 106. One or more deposition tools are used to deposit the first heterojunction layer 104, the second heterojunction layer 106, and the blanket gate separation layer 202 using a spin-coating technique, a physical vapor deposition (PVD) technique, an atomic layer deposition (ALD) technique, a chemical vapor deposition (CVD) technique, and/or another suitable deposition technique. In some implementations, a planarization tool may be used to planarize one or more of the first heterojunction layer 104, the second heterojunction layer 106, and the blanket gate separation layer 202.

As noted herein, the gate separation layers 110 may include a doped III-V material, such as p-doped GaN. The blanket gate separation layer 202 may be doped using, for example, an ion implant tool, to implant one or more dopants, such as a p-type material (e.g., boron (B) or germanium (Ge), among other examples), or an n-type material (e.g., phosphorous (P), arsenic (As), bismuth (Bi), and/or antimony (Sb), among other examples).

As shown in FIG. 2B, portions of the blanket gate separation layer 202 may be removed in an etching process to pattern the blanket gate separation layer 202 into the gate separation layers 110. One or more masking layers may be formed (e.g., using one or more deposition tools) on the blanket gate separation layer 202. The blanket gate separation layer 202 is etched to remove portions of the blanket gate separation layer 202. This results in formation of the gate separation layers 110, which may be arranged in an x-direction in the semiconductor device 100.

The gate separation layers 110 may be formed by patterning the one or more masking layers and etching the blanket gate separation layer 202 based on a pattern formed in one or more of the masking layers. The one or more masking layers may be patterned using photolithography techniques. An etch tool may be used to etch the blanket gate separation layer 202 based on the pattern using a dry etch technique (e.g., reactive ion etching), a wet etch technique, and/or a combination thereof.

The isolation region 108 is formed in the first heterojunction layer 104 and in the second heterojunction layer 106. In some implementations, the isolation region is a doped implant region that may be doped using, for example, an ion implant tool, to implant one or more dopants, such as a p-type material (e.g., boron (B) or germanium (Ge), among other examples), or an n-type material (e.g., phosphorous (P), arsenic (As), bismuth (Bi), and/or antimony (Sb), among other examples). The dopants may break lattice structures of the first heterojunction layer 104 (e.g., GaN layer) and of the second heterojunction layer 106 (e.g., AlGaN layer) to remove and/or prevent formation of 2DEG channel regions 132 where the isolation regions 108 are located.

Alternatively, where an isolation region includes an STI region, portions of the first heterojunction layer 104 and the second heterojunction layer 106 may be removed in an etching operation to form a recess in the first heterojunction layer 104 and in the second heterojunction layer 106. A deposition tool may be used to deposit dielectric material of the isolation region 108 in the recess using a PVD technique, an ALD technique, a CVD technique, an oxidation technique, and/or another suitable deposition technique. A planarization tool may then be used to perform a planarization or polishing operation (e.g., a chemical mechanical planarization (CMP) operation) to planarize the dielectric material of the isolation region such that the top surface of the dielectric layer is approximately co-planar with the top of the second heterojunction layer 106.

The dielectric layer 116 is deposited on the second heterojunction layer 106 and on the gate separation layers 110. A deposition tool may be used to deposit dielectric material of the dielectric layer 116 using a PVD technique, an ALD technique, a CVD technique, an oxidation technique, and/or another suitable deposition technique. Based on a pattern in a mask layer, an etch tool may be used to etch portions of the dielectric layer 116 to form recesses where the gate electrodes 112 and the source/drain electrode 114 are to be formed. In a case where part of the source/drain electrode 114 is formed in the second heterojunction layer 106, an underlying portion of the second heterojunction layer 106 may also be removed. In some implementations, the etch operation to etch portions of the dielectric layer 116 and the second heterojunction layer 106 to form the recesses includes a dry etch operation (e.g., a plasma-based etch operation, a gas-based etch operation), a wet chemical etch operation, and/or another type of etch operation.

A source/drain electrode 114 may be formed on the heterojunction structure including the first heterojunction layer 104 and the second heterojunction layer 106. A portion of the source/drain electrode 114 may be formed in the second heterojunction layer 106, where a portion of the second heterojunction layer 106 is recessed in an etching operation prior to depositing the source/drain electrode 114. Using a spin-coating technique, a CVD technique, a PVD technique, an ALD technique, and/or another deposition technique, a deposition tool may form the source/drain electrode 114 by depositing conductive material of the source/drain electrode 114 in the recess formed by etching the dielectric layer 116.

As further shown in FIG. 2B, gate electrodes 112 are formed on the gate separation layers 110. Using a spin-coating technique, a CVD technique, a PVD technique, an ALD technique, and/or another deposition technique, a deposition tool may form the gate electrodes 112 by depositing conductive material of the gate electrodes 112 in the recesses formed by etching the dielectric layer 116.

A first portion of the IMD layer 118 is deposited on the dielectric layer 116 and around portions of the gate electrodes 112 and the source/drain electrode 114. A deposition tool may be used to deposit dielectric material of the first portion of the IMD layer 118 using a PVD technique, an ALD technique, a CVD technique, an oxidation technique, and/or another suitable deposition technique. Based on a pattern in a mask layer, an etch tool may be used to etch portions of the first portion of the IMD layer 118 to form recesses where the gate contacts 120 and source/drain contact 122 are to be formed. Using a spin-coating technique, a CVD technique, a PVD technique, an ALD technique, and/or another deposition technique, a deposition tool may form the gate contacts 120 and source/drain contact 122 by depositing conductive material of the gate contacts 120 and source/drain contact 122 in the recesses formed by etching the first portion of the IMD layer 118. A planarization tool may then be used to perform a planarization or polishing operation (e.g., a CMP operation) to planarize the dielectric material of the first portion of the IMD layer 118 such that the top surface of the first portion of the IMD layer 118 is approximately co-planar with the top of the gate contacts 120 and source/drain contact 122.

As shown in FIG. 2C, a second portion of the IMD layer 118 is deposited on the first portion of the IMD layer 118. A deposition tool may be used to deposit dielectric material of the dielectric layer 116 using a PVD technique, an ALD technique, a CVD technique, an oxidation technique, and/or another suitable deposition technique. Remaining conductive structures including first metallization structures 124, second metallization structures 126, and interconnect structures 128 are formed using the same or similar techniques as those used for forming the gate electrodes 112, source/drain electrode 114, gate contacts 120, and source/drain contact 122.

As shown in FIG. 2D, an adhesive is deposited on exposed surfaces of the IMD layer 118, and on exposed surfaces of the second metallization structures 126 to attach a carrier wafer 204 to the semiconductor device 100. The adhesive may be, for example, a polymeric material, such as a polyimide-based material, and/or a thermoplastic polymer. The carrier wafer 204 may be, for example, a glass carrier wafer. The resulting structure is flipped (e.g., rotated 180 degrees) using a wafer/die transport tool so that the substrate 102 is at a top of the structure instead of a bottom of the structure in the z-direction, and the second metallization structures 126 and IMD layer 118 are at a bottom of the structure instead of a top of the structure in the z-direction. The carrier wafer 204 can be attached to the wafer/die transport tool to perform the rotation.

Following the flipping process, a portion of the substrate 102 is removed in a grinding process to thin the substrate 102 (e.g., to reduce a z-direction thickness of the substrate 102). The substrate 102 may be thinned to reduce the processing time and/or etchant consumption of an etch operation to remove portions of the substrate 102. A planarization tool (e.g., a grinding tool) may perform a grinding operation and/or a CMP process to mechanically grind silicon or sapphire material away from the substrate 102.

As shown in FIG. 2E, following the grinding operation, recesses 206 are formed from the backside of the semiconductor device 100. The recesses 206 are formed through the substrate 102 and into the first heterojunction layer 104. In order to form the recesses 206, a dielectric masking layer may be formed on the substrate 102. The dielectric masking layer may include a silicon oxynitride material (SiON) and/or another suitable dielectric material. A deposition tool may be used to deposit the dielectric masking layer using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer after the dielectric masking layer is deposited.

A photoresist layer may be formed above the dielectric masking layer, and a pattern may be formed in the photoresist layer. A deposition tool may be used to form the photoresist layer on the dielectric masking layer (e.g., using a spin-coating technique or another suitable deposition technique). In some implementations, a bottom antireflective coating (BARC) is first deposited on the dielectric masking layer, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer based on the pattern in the photoresist layer, to transfer the pattern to the dielectric masking layer. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer compared to the material of the underlying substrate 102. Thus, the etch operation may stop on the substrate 102 with minimal etching to the substrate 102.

Another etch operation may be performed to etch through the substrate 102, and through part of the first heterojunction layer 104 to form recesses 206, where bottom surfaces of the recesses are in the first heterojunction layer 104. The etch operation may include, for example, a gas-based etch operation in which a different type of etchant is used, as compared to the etchant that was used to transfer the pattern to the dielectric masking layer. Thus, the semiconductor device 100 may be transferred from a first etch tool (in which the pattern was transferred to the dielectric masking layer) to a second etch tool (in which the substrate 102, and the first heterojunction layer 104 are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

In some implementations, an x-direction distance (e.g., width) of the recesses 206 (indicated in FIG. 2E as a dimension D3) is included in a range of approximately 0.5 microns to approximately 3 microns. If the dimension D3 is less than approximately 0.5 microns, the resulting source/drain electrodes 130 formed in the recesses 206 will not be large enough, causing an unwanted increase in source/drain resistance. A dimension D3 greater than approximately 3 microns may result in warpage, cracking, and/or other damage to the source/drain electrodes 130. However, other values and/or ranges for the x-direction distance of the recesses 206 are within the scope of the present disclosure.

As shown in FIG. 2F, one or more deposition tools may be used to deposit the source/drain electrodes 130 using a PVD technique, an ALD technique, a CVD technique, an electroplating technique (e.g., an electro-chemical plating technique), and/or another suitable deposition technique. In some implementations, a planarization tool may be used to planarize the source/drain electrodes 130 and a top surface of the substrate 102 to remove remaining portions of the photoresist layer, and/or the dielectric masking layer on the top surface of the substrate 102 after the source/drain electrodes 130 are deposited. In some implementations, a seed layer is deposited in each of the recesses 206 before depositing the conductive material of the source/drain electrodes 130 in the recesses 206. The seed layer may include, for example, titanium (Ti), aluminum (Al), nickel (Ni), titanium nitride (TiN), tungsten (W), tantalum (Ta), and/or gold (Au). For example, the seed layer may include Ti/Al/Ti/TiN, Ti/Al/Ni/TiN, Ti/Al/Ti/W, Ti/Al/Ti/Ta, Ti/Al/Ti/Au, or a combination thereof.

As further shown in FIG. 2F, the conductive layer 134 is formed over and/or on the substrate 102, including the source/drain electrodes 130 formed in the substrate 102 and in the first heterojunction layer 104. The conductive layer 134 is in direct contact with the source/drain electrodes 130. A deposition tool and/or a plating tool may be used to deposit the conductive layer 134 using a PVD technique, an ALD technique, a CVD technique, an electroplating technique (e.g., an electro-chemical plating technique), and/or another suitable deposition technique. In some implementations, the planarization tool may be used to planarize the conductive layer 134 after the conductive layer 134 is deposited. The conductive layer 134 includes aluminum (Al), aluminum copper (AlCu), tungsten (W), cobalt (Co), ruthenium (Ru), titanium (Ti), gold (Au), nickel (Ni), and/or another conductive material.

As shown in FIG. 2G, the ground plate 136 is formed over and/or on the conductive layer 134. In some implementations, the ground plate 136 may be bonded to the conductive layer 134 using one or more thermal interface materials (TIMs) between the ground plate 136 and the conductive layer 134. The TIMs may facilitate dissipation of heat from the HEMT devices. The TIMs may include liquid polymer pastes, wax pads, aluminum pads, graphite pads, silicone pads, tapes, solders, gels, and/or other materials.

In some implementations, a deposition tool and/or a plating tool may be used to deposit the ground plate 136 using a PVD technique, an ALD technique, a CVD technique, an electroplating technique (e.g., an electro-chemical plating technique), and/or another suitable deposition technique. In some implementations, the planarization tool may be used to planarize the ground plate 136 after the ground plate 136 is deposited. The ground plate 136 includes aluminum (Al), aluminum copper (AlCu), tungsten (W), cobalt (Co), ruthenium (Ru), titanium (Ti), gold (Au), nickel (Ni), and/or another conductive material.

As shown in FIG. 2H, the ground plate 136 includes a ground voltage connection 138, and the carrier wafer 204 may be removed. In some implementations, following removal of the carrier wafer 204, the second metallization structures 126 may be coupled to connection structures including, for example, solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, bonding pads, and/or other types of connection structures.

As indicated above, FIGS. 2A-2H are provided as an example. Other examples may differ from what is described with regard to FIGS. 2A-2H.

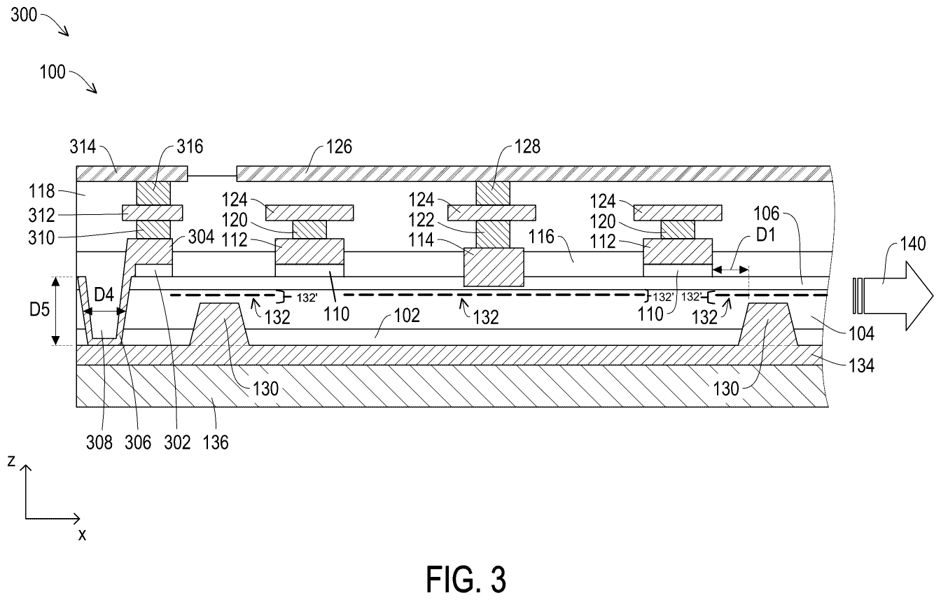

FIG. 3 is a diagram of an example implementation 300 of the semiconductor device 100 (e.g., a gallium nitride (GaN)-based semiconductor device) described herein. As shown in FIG. 3, the example implementation 300 of the semiconductor device 100 may include a similar arrangement of components as the example implementation of the semiconductor device 100 illustrated and described in connection with FIG. 1. For example, the example implementation 300 may include components 102-106 and 110-140. The example implementation 300 may further include another gate separation layer 302 and another gate electrode 304. The gate separation layer 302 may be the same as or similar to the gate separation layers 110. The gate electrode 304 may be the same as or similar to the gate electrodes 112. For example, the gate separation layer 302 may include the same material(s) as the gate separation layers 110, and may be formed in the same or similar process(es) as the process(es) for forming the gate separation layers 110. The gate electrode 304 may include the same material(s) as the gate electrodes 112, and may be formed in the same or similar process(es) as the process(es) for forming the gate electrodes 112.

The example implementation 300 may further include an interconnect structure 306 connected between the gate electrode 304 and the conductive layer 134. In some implementations, the interconnect structure 306 is formed from the same material(s) as the gate electrode 304, and lines side and bottom surfaces of a recess in which the interconnect structure 306 is formed. A dielectric fill layer 308 fills in a remaining portion of the recess in which the interconnect structure 306 is formed. The dielectric fill layer 308 may be the same material(s) as the dielectric layer 116. The interconnect structure 306 (also referred to herein as a through-gallium-via (TGV)) is formed through the second heterojunction layer 106, the first heterojunction layer 104, and the substrate 102 to land on the conductive layer 134. The interconnect structure 306 is in direct contact with the conductive layer 134.

The example implementation 300 may further include another gate contact 310, another first metallization structure 312, another second metallization structure 314, and another interconnect structure 316. The gate contact 310 may be the same as or similar to the gate contacts 120. For example, the gate contact 310 may include the same material(s) as the gate contacts 120, and may be formed in the same or similar process(es) as the process(es) for forming the gate contacts 120. The first metallization structure 312 may be the same as or similar to the first metallization structures 124. For example, the first metallization structure 312 may include the same material(s) as the first metallization structures 124, and may be formed in the same or similar process(es) as the process(es) for forming the first metallization structures 124. The second metallization structure 314 may be the same as or similar to the second metallization structures 126. For example, the second metallization structure 314 may include the same material(s) as the second metallization structures 126, and may be formed in the same or similar process(es) as the process(es) for forming the second metallization structures 126. The second metallization structures 314 and 126 are spaced apart from each other. The interconnect structure 316 may be the same as or similar to the interconnect structure 128. For example, the interconnect structure 316 may include the same material(s) as the interconnect structure 128, and may be formed in the same or similar process(es) as the process(es) for forming the interconnect structure 128.

The interconnect structure 306 is also in direct contact with the gate electrode 304, which may receive a voltage and/or signal from the second metallization structure 314 through the interconnect structure 316, first metallization structure 312, and gate contact 310. In some implementations, an x-direction dimension D4 (e.g., width) of the recess in which the interconnect structure 306 and dielectric fill layer 308 are formed is included in a range of approximately 0.5 microns to approximately 10 microns. However, other values and/or ranges for the x-direction dimension D4 are within the scope of the present disclosure. In some implementations, a z-direction dimension D5 (e.g., height or depth) of the recess in which the interconnect structure 306 and dielectric fill layer 308 are formed is included in a range of approximately 2 microns to approximately 100 microns. However, other values and/or ranges for the z-direction dimension D5 are within the scope of the present disclosure.

As indicated above, FIG. 3 is provided as an example. Other examples may differ from what is described with regard to FIG. 3.

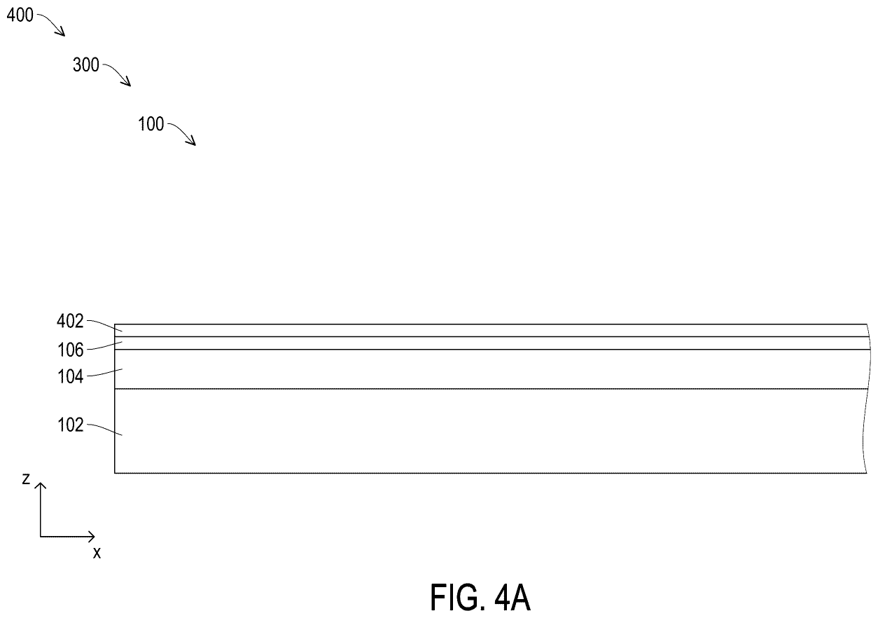

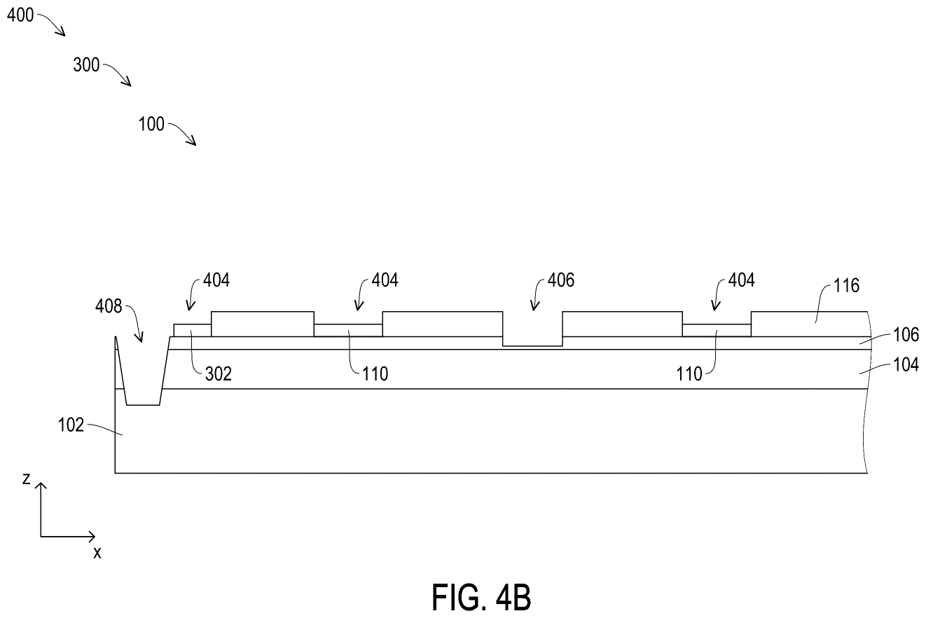

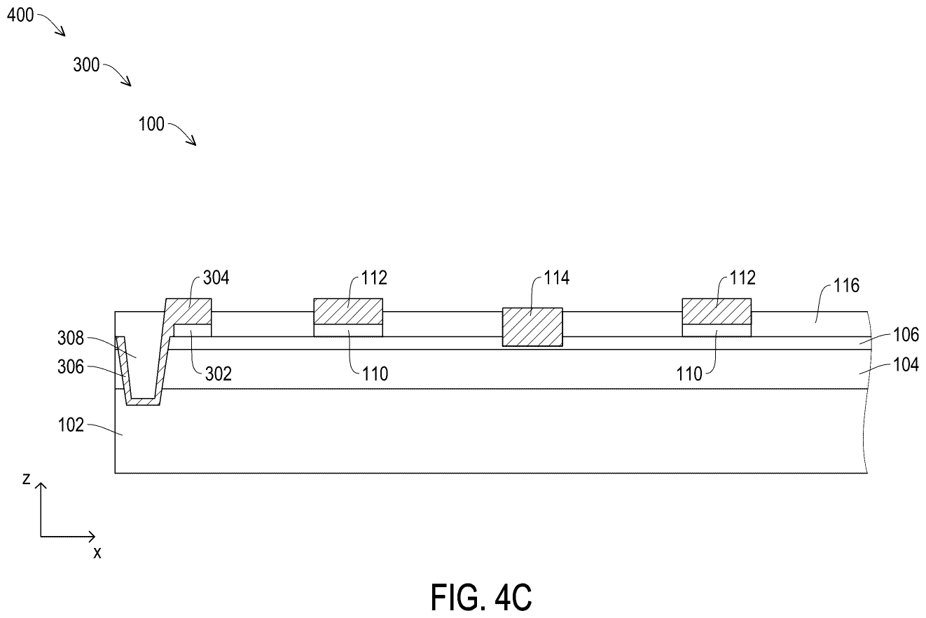

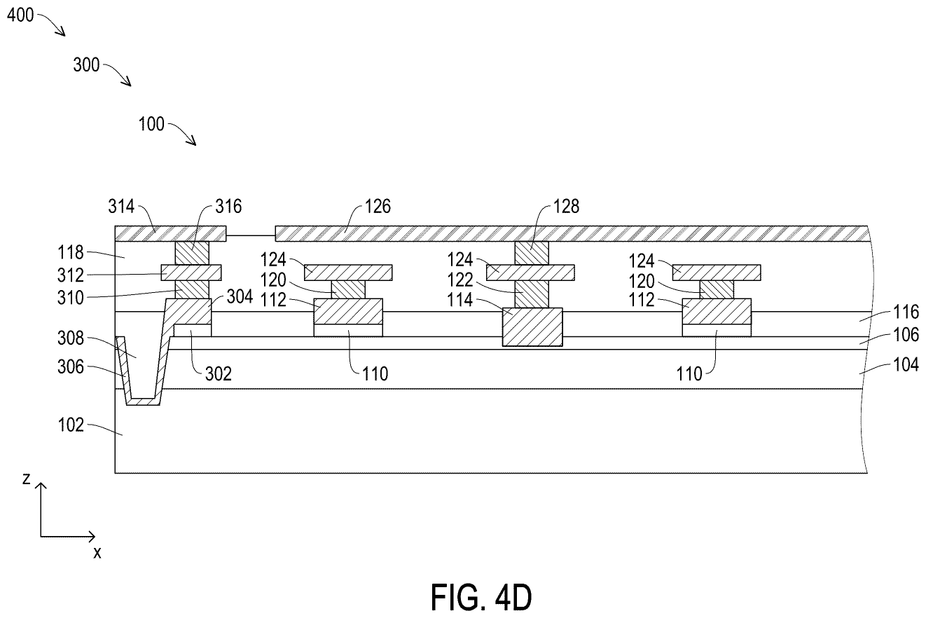

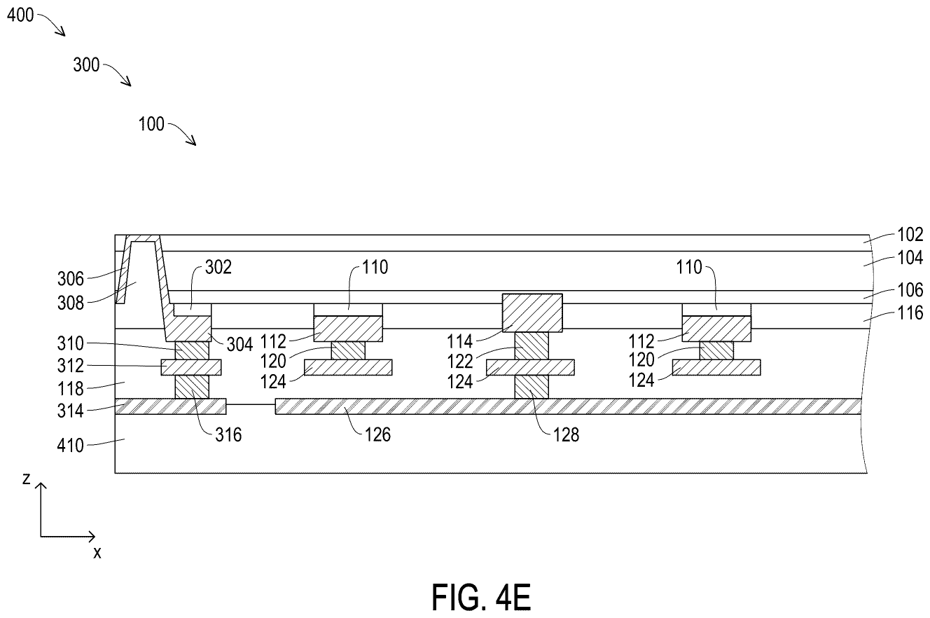

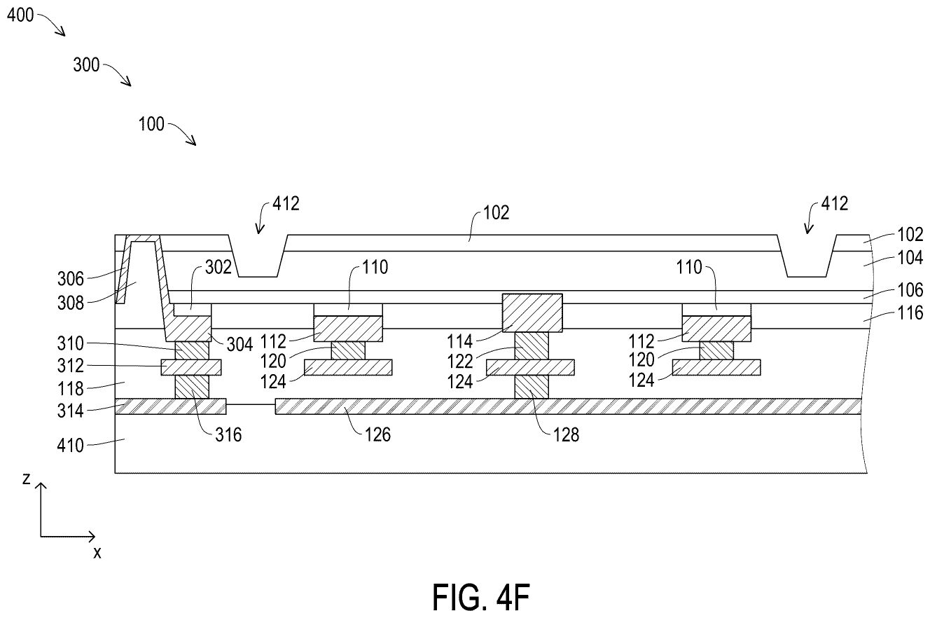

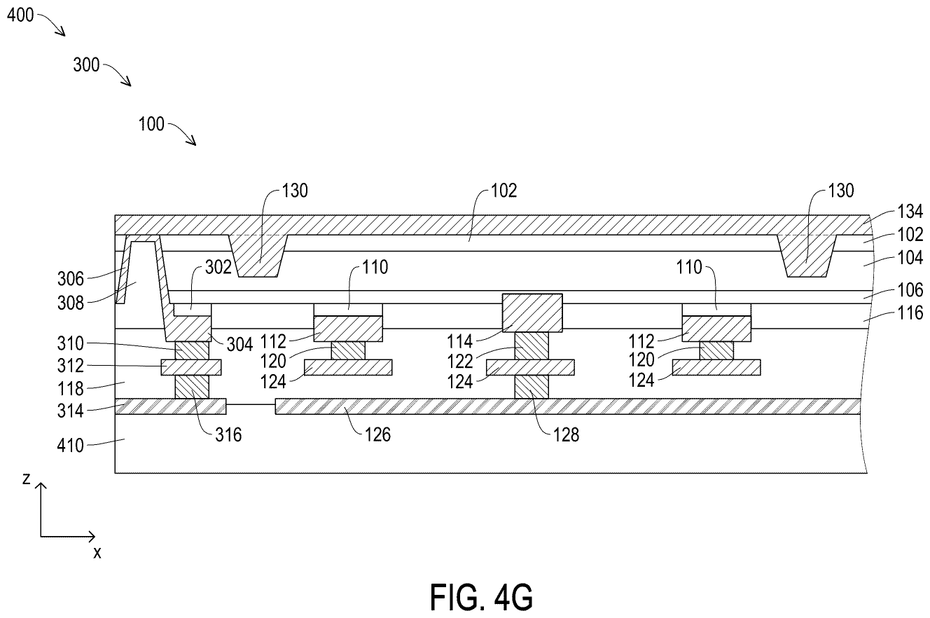

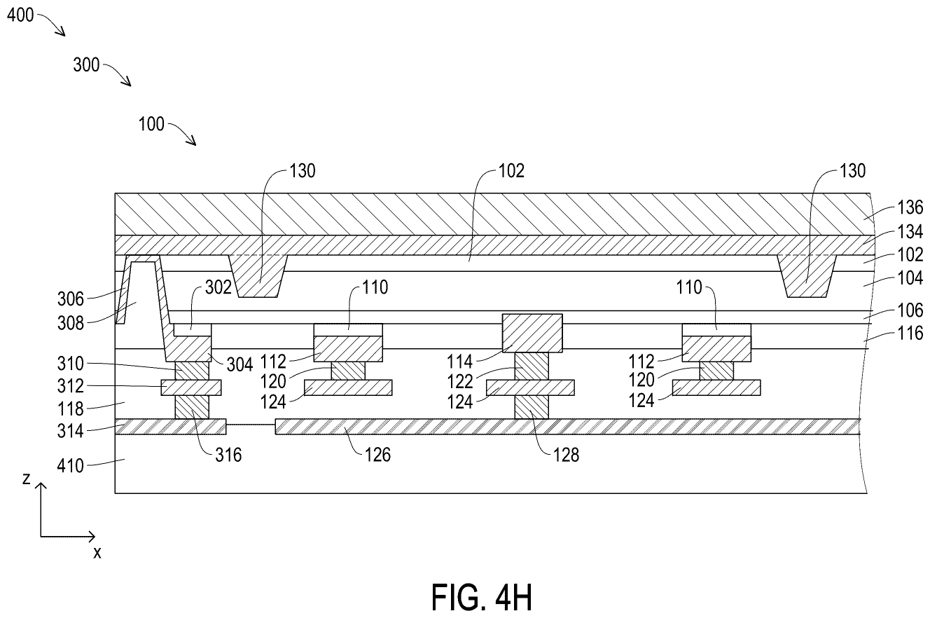

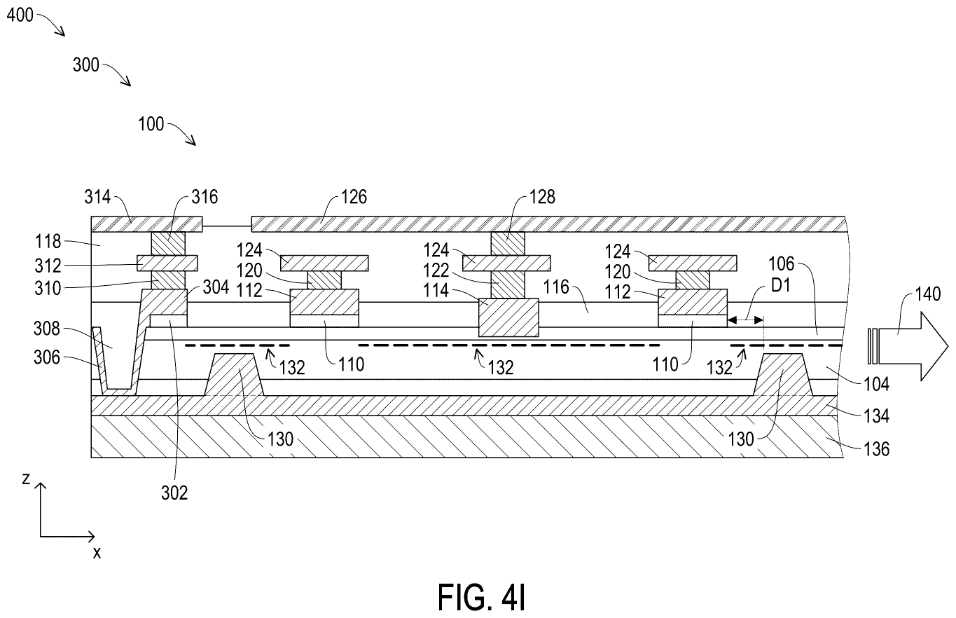

FIGS. 4A-4I are diagrams of an example implementation 400 of forming the semiconductor device 100 of the example implementation 300. One or more semiconductor processing tools may be used to form one or more portions of the semiconductor device 100 of the example implementation 300. In some implementations, forming the semiconductor device 100 of the example implementation 300 may include using a deposition tool to deposit one or more layers and/or structures. In some implementations, forming the semiconductor device 100 of the example implementation 300 may include using an exposure tool to expose photoresist layers to form patterns in the photoresist layers, and using an etch tool to etch one or more other layers to form one or more structures of the semiconductor device 100 of the example implementation 300. As another example, a planarization tool may be used to planarize portions of the semiconductor device 100 of the example implementation 300. As another example, a plating tool may be used to deposit metal structures and/or layers of the semiconductor device 100 of the example implementation 300.

As shown in FIG. 4A, a substrate 102 is provided. The first heterojunction layer 104 (e.g., a GaN layer) is deposited on the substrate 102, the second heterojunction layer 106 (e.g., an AlGaN layer) is deposited on the first heterojunction layer 104, and a blanket gate separation layer 402 is deposited on the second heterojunction layer 106. One or more deposition tools are used to deposit the first heterojunction layer 104, the second heterojunction layer 106, and the blanket gate separation layer 402 using a spin-coating technique, PVD technique, an ALD technique, a CVD technique, and/or another suitable deposition technique. In some implementations, a planarization tool may be used to planarize one or more of the first heterojunction layer 104, the second heterojunction layer 106, and the blanket gate separation layer 402. The blanket gate separation layer 402 is the same as the blanket gate separation layer 202, except that it is referred to with reference numeral “402” rather than reference numeral “202” since it is part of the process flow in the example implementation 400.

The gate separation layers 110 and 302 may include a doped III-V material, such as p-doped GaN. The blanket gate separation layer 402 may be doped using, for example, an ion implant tool, to implant one or more dopants, such as a p-type material (e.g., boron (B) or germanium (Ge), among other examples), or an n-type material (e.g., phosphorous (P), arsenic (As), bismuth (Bi), and/or antimony (Sb), among other examples).

As shown in FIG. 4B, similar to the blanket gate separation layer 202, portions of the blanket gate separation layer 402 may be removed in an etching process to pattern the blanket gate separation layer 402 into the gate separation layers 110 and 302.

In some implementations, the dielectric layer 116 is deposited on the second heterojunction layer 106 and on the gate separation layers 110 and 302. A deposition tool may be used to deposit dielectric material of the dielectric layer 116 using a PVD technique, an ALD technique, a CVD technique, an oxidation technique, and/or another suitable deposition technique. Based on a pattern in a mask layer, an etch tool may be used to etch portions of the dielectric layer 116 to form recesses 404 where the gate electrodes 112 and 304 are to be formed, and a recess 406 where the source/drain electrode 114 is to be formed. In a case where part of the source/drain electrode 114 is formed in the second heterojunction layer 106, an underlying portion of the second heterojunction layer 106 may also be removed. In addition, a recess 408 is formed through the second heterojunction layer 106, the first heterojunction layer 104, and part of the substrate 102 where the interconnect structure 306 is to be formed. In some implementations, the etch operation to etch portions of the dielectric layer 116, the second heterojunction layer 106, the first heterojunction layer 104, and the substrate 102 to form the recesses 404, 406, and 408 includes a dry etch operation (e.g., a plasma-based etch operation, a gas-based etch operation), a wet chemical etch operation, and/or another type of etch operation.

As shown in FIG. 4C, a source/drain electrode 114 may be formed on the heterojunction structure including the first heterojunction layer 104 and the second heterojunction layer 106. A portion of the source/drain electrode 114 may be formed in the second heterojunction layer 106, where a portion of the second heterojunction layer 106 is recessed in an etching operation prior to depositing the source/drain electrode 114. Using a spin-coating technique, a CVD technique, a PVD technique, an ALD technique, and/or another deposition technique, a deposition tool may form the source/drain electrode 114 by depositing conductive material of the source/drain electrode 114 in the recess 406 formed by etching the dielectric layer 116.

As further shown in FIG. 4C, gate electrodes 112 are formed on the gate separation layers 110, and a gate electrode 304 is formed on the gate separation layer 302. Using a spin-coating technique, a CVD technique, a PVD technique, an ALD technique, and/or another deposition technique, a deposition tool may form the gate electrodes 112 and 304 by depositing conductive material of the gate electrodes 112 and 304 in the recesses 404 formed by etching the dielectric layer 116. Using a conformal deposition technique, (e.g., a CVD technique, an ALD technique, and/or another deposition technique), the interconnect structure 306 is formed in the recess 408. A deposition tool may form the interconnect structure 306 by depositing conductive material of the interconnect structure 306 in the recess 408 formed by etching the dielectric layer 116, the second heterojunction layer 106, the first heterojunction layer 104, and part of the substrate 102. The interconnect structure 306 lines side surfaces and a bottom surface of the recess 408, and is connected to the gate electrode 304. In some implementations, the interconnect structure 306 and the gate electrode 304 are deposited at a same time, and include the same material(s). Following the deposition of the interconnect structure 306, the dielectric fill layer 308 is deposited in the recess 408 on the interconnect structure 306 to fill in a remaining portion of the recess 408. The dielectric fill layer 308 may include the same material as the dielectric layer 116, and may be deposited by a deposition tool using a PVD technique, an ALD technique, a CVD technique, an oxidation technique, and/or another suitable deposition technique.

Referring to FIG. 4D, a first portion of the IMD layer 118 is deposited on the dielectric layer 116 and around portions of the gate electrodes 112 and 304, the source/drain electrode 114 and the interconnect structure 306. A deposition tool may be used to deposit dielectric material of the first portion of the IMD layer 118 using a PVD technique, an ALD technique, a CVD technique, an oxidation technique, and/or another suitable deposition technique. Based on a pattern in a mask layer, an etch tool may be used to etch portions of the first portion of the IMD layer 118 to form recesses where the gate contacts 120 and 310 and source/drain contact 122 are to be formed. Using a spin-coating technique, a CVD technique, a PVD technique, an ALD technique, and/or another deposition technique, a deposition tool may form the gate contacts 120 and 310, and source/drain contact 122 by depositing conductive material of the gate contacts 120 and 310, and source/drain contact 122 in the recesses formed by etching the first portion of the IMD layer 118. A planarization tool may then be used to perform a planarization or polishing operation (e.g., a CMP operation) to planarize the dielectric material of the first portion of the IMD layer 118 such that the top surface of the first portion of the IMD layer 118 is approximately co-planar with the top of the gate contacts 120 and 310, and the source/drain contact 122.

A second portion of the IMD layer 118 is deposited on the first portion of the IMD layer 118. A deposition tool may be used to deposit dielectric material of the dielectric layer 116 using a PVD technique, an ALD technique, a CVD technique, an oxidation technique, and/or another suitable deposition technique. Remaining conductive structures including first metallization structures 124 and 312, second metallization structures 126 and 314, and interconnect structures 128 and 316 are formed using the same or similar techniques as those used for forming the gate electrodes 112 and 304, source/drain electrode 114, gate contacts 120 and 310, and source/drain contact 122.

As shown in FIG. 4E, an adhesive is deposited on exposed surfaces of the IMD layer 118, and on exposed surfaces of the second metallization structures 126 and 314 to attach a carrier wafer 410 to the semiconductor device 100. The adhesive may be, for example, a polymeric material, such as a polyimide-based material, and/or a thermoplastic polymer. Similar to the carrier wafer 204, the carrier wafer 410 may be, for example, a glass carrier wafer. The resulting structure is flipped (e.g., rotated 180 degrees) using a wafer/die transport tool so that the substrate 102 is at a top of the structure instead of a bottom of the structure in the z-direction, and the second metallization structures 126 and 314, and IMD layer 118 are at a bottom of the structure instead of a top of the structure in the z-direction. The carrier wafer 410 can be attached to the wafer/die transport tool to perform the rotation.

Following the flipping process, a portion of the substrate 102 is removed in a grinding process to thin the substrate 102 (e.g., to reduce a z-direction thickness of the substrate 102). The substrate 102 may be thinned to reduce the processing time and/or etchant consumption of an etch operation to remove portions of the substrate 102. A planarization tool (e.g., a grinding tool) may perform a grinding operation and/or a CMP process to mechanically grind silicon or sapphire material away from the substrate 102.

As shown in FIG. 4F, following the grinding operation, recesses 412 are formed from the backside of the semiconductor device 100. The recesses 412 are formed through the substrate 102 and into the first heterojunction layer 104. The recesses 412 are formed using the same or similar processes as those described in connection with FIG. 2E for forming the recesses 206.

As shown in FIG. 4G, using the same or similar processes as those described in connection with FIG. 2F, one or more deposition tools may be used to deposit the source/drain electrodes 130 and the conductive layer 134 using a PVD technique, an ALD technique, a CVD technique, an electroplating technique (e.g., an electro-chemical plating technique), and/or another suitable deposition technique. The conductive layer 134 is formed over and/or on the substrate 102, including the source/drain electrodes 130 formed in the substrate 102 and in the first heterojunction layer 104. The conductive layer 134 is in direct contact with the source/drain electrodes 130. The conductive layer 134 is direct contact with a surface of the interconnect structure 306. The interconnect structure 306 is formed through the substrate 102, the first heterojunction layer 104, and through the second heterojunction layer 106.

As shown in FIG. 4H, using the same or similar processes as those described in connection with FIG. 2G, the ground plate 136 is formed over and/or on the conductive layer 134. The ground plate 136 may include a connection to a ground voltage (e.g., ground voltage connection 138).

As shown in FIG. 4I, he carrier wafer 410 may be removed. In some implementations, following removal of the carrier wafer 410, the second metallization structures 126 and 314 may be coupled to connection structures including, for example, solder balls, solder bumps, contact pads (e.g., LGA pads), contact pins (e.g., PGA pins), UBM connections, microbumps, BGA balls, C4 bumps, bonding pads, and/or other types of connection structures.

As indicated above, FIGS. 4A-4I are provided as an example. Other examples may differ from what is described with regard to FIGS. 4A-4I.

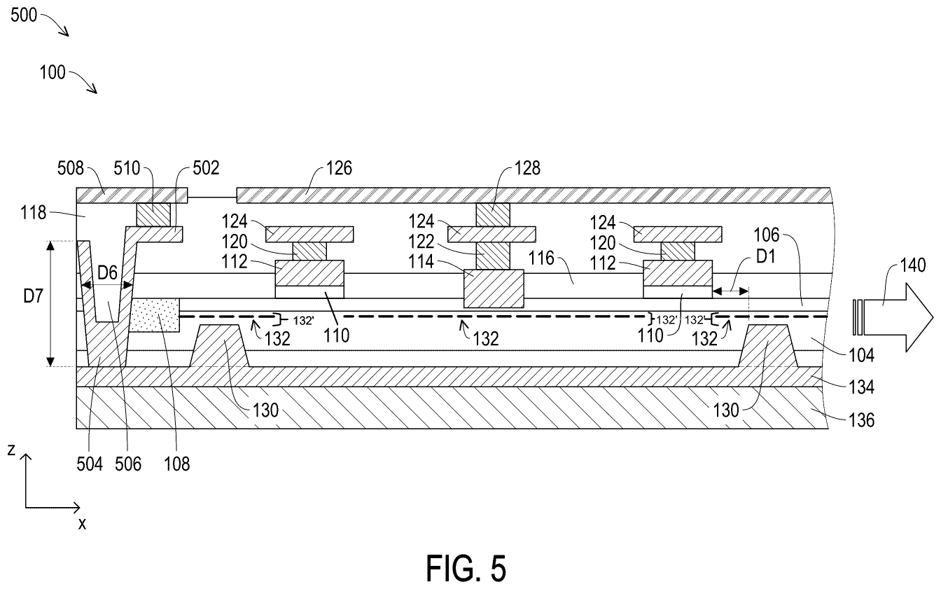

FIG. 5 is a diagram of an example implementation 500 of the semiconductor device 100 (e.g., a gallium nitride (GaN)-based semiconductor device) described herein. As shown in FIG. 5, the example implementation 500 of the semiconductor device 100 may include a similar arrangement of components as the example implementation of the semiconductor device 100 illustrated and described in connection with FIG. 1. For example, the example implementation 500 may include components 102-140. The example implementation 500 may further include another first metallization structure 502 and an interconnect structure 504 connected between the first metallization structure 502 and the conductive layer 134. In some implementations, the first metallization structure 502 may be the same as or similar to the first metallization structures 124. For example, the first metallization structure 502 may include the same material(s) as the first metallization structures 124, and may be formed in the same or similar process(es) as the process(es) for forming the first metallization structures 124. In some implementations, the interconnect structure 306 is formed from the same material(s) as the first metallization structure 502, and lines side and bottom surfaces of a recess in which the interconnect structure 504 is formed. A dielectric fill layer 506 fills in a remaining portion of the recess in which the interconnect structure 504 is formed. The dielectric fill layer 506 may be the same material(s) as the IMD layer 118. The interconnect structure 504 (also referred to herein as a through-gallium-via (TGV)) is formed through the IMD layer 118, the dielectric layer 116, the second heterojunction layer 106, the first heterojunction layer 104, and the substrate 102 to land on the conductive layer 134. The interconnect structure 504 is in direct contact with the conductive layer 134.

The example implementation 500 may further include another second metallization structure 508, and another interconnect structure 510. The second metallization structure 508 may be the same as or similar to the second metallization structures 126. For example, the second metallization structure 508 may include the same material(s) as the second metallization structures 126, and may be formed in the same or similar process(es) as the process(es) for forming the second metallization structures 126. The second metallization structures 508 and 126 are spaced apart from each other. The interconnect structure 510 may be the same as or similar to the interconnect structure 128. For example, the interconnect structure 510 may include the same material(s) as the interconnect structure 128, and may be formed in the same or similar process(es) as the process(es) for forming the interconnect structure 128.

The interconnect structure 504 is also in direct contact with the first metallization structure 502, which may receive a voltage and/or signal from the second metallization structure 508 through the interconnect structure 510, and transmit the voltage and/or signal to the conductive layer 134 and/or source/drain electrodes 130. In some implementations, an x-direction dimension D6 (e.g., width) of the recess in which the interconnect structure 504 and dielectric fill layer 506 are formed is included in a range of approximately 0.5 microns to approximately 10 microns. However, other values and/or ranges for the x-direction dimension D6 are within the scope of the present disclosure. In some implementations, a z-direction dimension D7 (e.g., height or depth) of the recess in which the interconnect structure 504 and dielectric fill layer 506 are formed is included in a range of approximately 2 microns to approximately 100 microns. However, other values and/or ranges for the z-direction dimension D7 are within the scope of the present disclosure.

As indicated above, FIG. 5 is provided as an example. Other examples may differ from what is described with regard to FIG. 5.

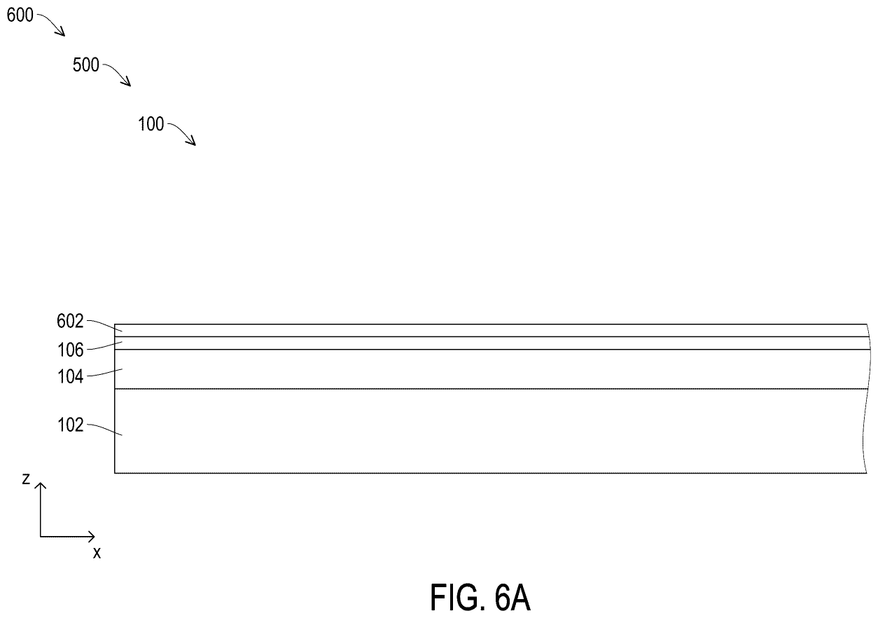

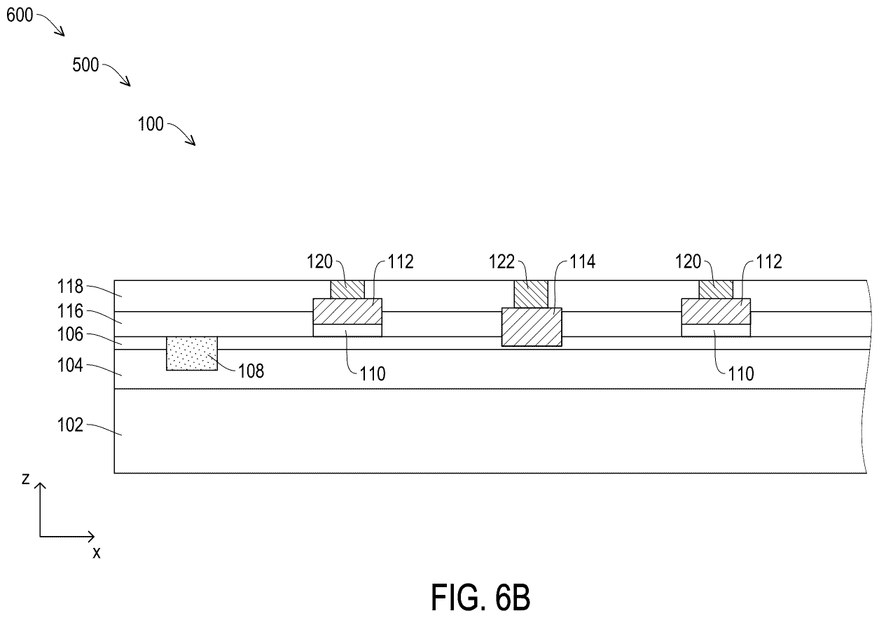

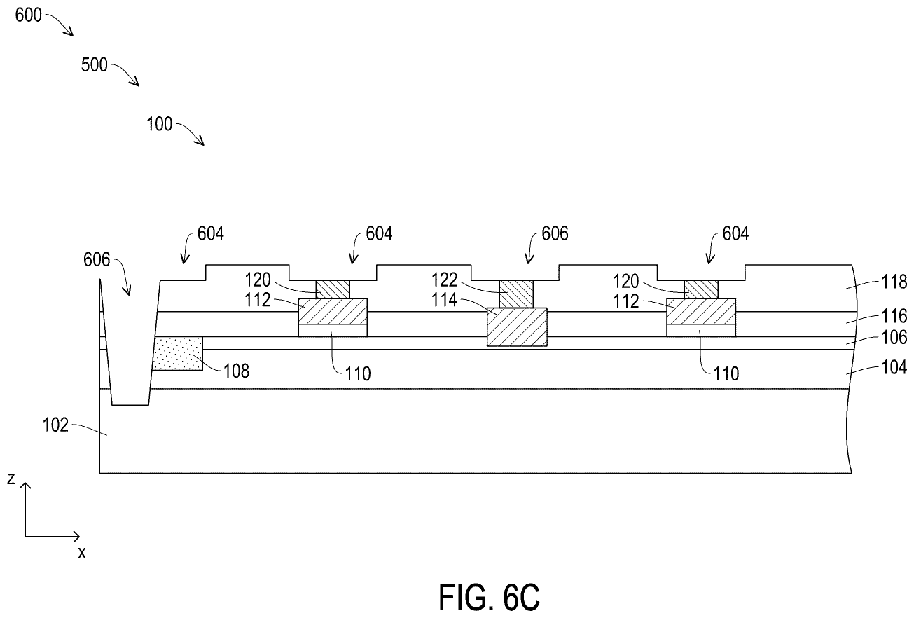

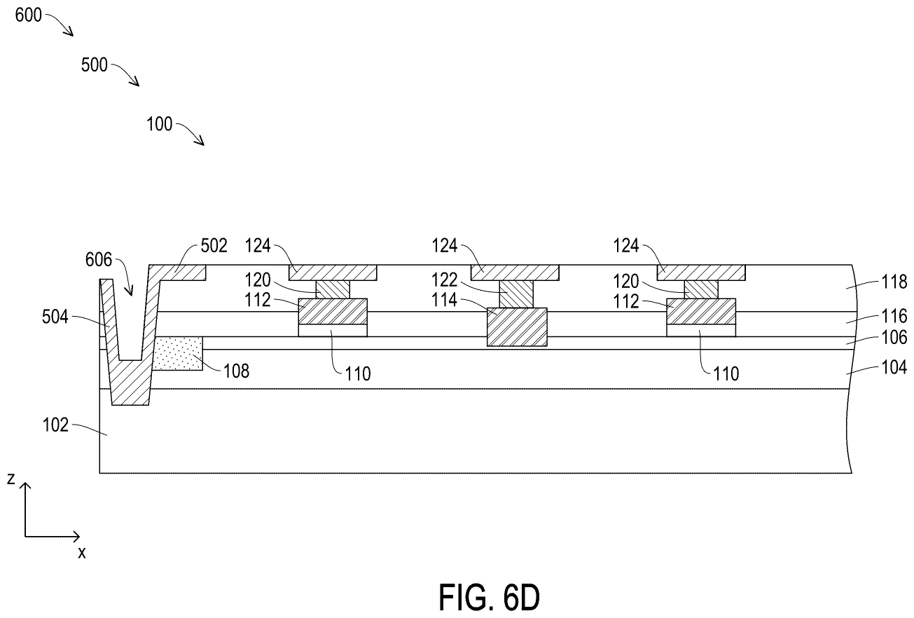

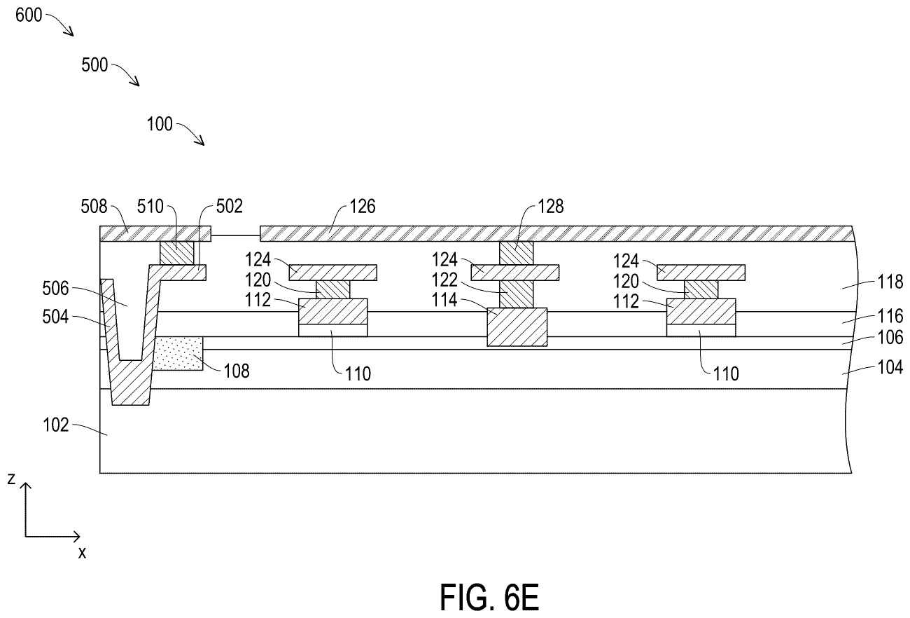

FIGS. 6A-6E are diagrams of an example implementation 600 of forming the semiconductor device 100 of the example implementation 500. One or more semiconductor processing tools may be used to form one or more portions of the semiconductor device 100 of the example implementation 500. In some implementations, forming the semiconductor device 100 of the example implementation 500 may include using a deposition tool to deposit one or more layers and/or structures. In some implementations, forming the semiconductor device 100 of the example implementation 500 may include using an exposure tool to expose photoresist layers to form patterns in the photoresist layers, and using an etch tool to etch one or more other layers to form one or more structures of the semiconductor device 100 of the example implementation 500. As another example, a planarization tool may be used to planarize portions of the semiconductor device 100 of the example implementation 500. As another example, a plating tool may be used to deposit metal structures and/or layers of the semiconductor device 100 of the example implementation 500.

As shown in FIG. 6A, a substrate 102 is provided. The first heterojunction layer 104 (e.g., a GaN layer) is deposited on the substrate 102, the second heterojunction layer 106 (e.g., an AlGaN layer) is deposited on the first heterojunction layer 104, and a blanket gate separation layer 602 is deposited on the second heterojunction layer 106. One or more deposition tools are used to deposit the first heterojunction layer 104, the second heterojunction layer 106, and the blanket gate separation layer 602 using a spin-coating technique, PVD technique, an ALD technique, a CVD technique, and/or another suitable deposition technique. In some implementations, a planarization tool may be used to planarize one or more of the first heterojunction layer 104, the second heterojunction layer 106, and the blanket gate separation layer 602. The blanket gate separation layer 602 is the same as the blanket gate separation layer 202, except that it is referred to with reference numeral “602” rather than reference numeral “202” since it is part of the process flow in the example implementation 600.

The gate separation layers 110 may include a doped III-V material, such as p-doped GaN. The blanket gate separation layer 602 may be doped using, for example, an ion implant tool, to implant one or more dopants, such as a p-type material (e.g., boron (B) or germanium (Ge), among other examples), or an n-type material (e.g., phosphorous (P), arsenic (As), bismuth (Bi), and/or antimony (Sb), among other examples).

As shown in FIG. 6B, similar to the blanket gate separation layer 202, portions of the blanket gate separation layer 602 may be removed in an etching process to pattern the blanket gate separation layer 602 into the gate separation layers 110.

In some implementations, the dielectric layer 116 is deposited on the second heterojunction layer 106 and on the gate separation layers 110. A deposition tool may be used to deposit dielectric material of the dielectric layer 116 using a PVD technique, an ALD technique, a CVD technique, an oxidation technique, and/or another suitable deposition technique. Based on a pattern in a mask layer, an etch tool may be used to etch portions of the dielectric layer 116 to form recesses where the gate electrodes 112 and 304 are to be formed, and a recess where the source/drain electrode 114 is to be formed. In a case where part of the source/drain electrode 114 is formed in the second heterojunction layer 106, an underlying portion of the second heterojunction layer 106 may also be removed. In some implementations, the etch operation to etch portions of the dielectric layer 116 and the second heterojunction layer 106 to form the recesses includes a dry etch operation (e.g., a plasma-based etch operation, a gas-based etch operation), a wet chemical etch operation, and/or another type of etch operation.

As further shown in FIG. 6B, a source/drain electrode 114 may be formed on the heterojunction structure including the first heterojunction layer 104 and the second heterojunction layer 106. A portion of the source/drain electrode 114 may be formed in the second heterojunction layer 106, where a portion of the second heterojunction layer 106 is recessed in an etching operation prior to depositing the source/drain electrode 114. Using a spin-coating technique, a CVD technique, a PVD technique, an ALD technique, and/or another deposition technique, a deposition tool may form the source/drain electrode 114 by depositing conductive material of the source/drain electrode 114 in the recess formed by etching the dielectric layer 116.

Gate electrodes 112 are formed on the gate separation layers 110. Using a spin-coating technique, a CVD technique, a PVD technique, an ALD technique, and/or another deposition technique, a deposition tool may form the gate electrodes 112 by depositing conductive material of the gate electrodes 112 in the recesses formed by etching the dielectric layer 116.

A first portion of the IMD layer 118 is deposited on the dielectric layer 116 and around portions of the gate electrodes 112 and the source/drain electrode 114. A deposition tool may be used to deposit dielectric material of the first portion of the IMD layer 118 using a PVD technique, an ALD technique, a CVD technique, an oxidation technique, and/or another suitable deposition technique. Based on a pattern in a mask layer, an etch tool may be used to etch portions of the first portion of the IMD layer 118 to form recesses where the gate contacts 120 and source/drain contact 122 are to be formed. Using a spin-coating technique, a CVD technique, a PVD technique, an ALD technique, and/or another deposition technique, a deposition tool may form the gate contacts 120, and source/drain contact 122 by depositing conductive material of the gate contacts 120, and source/drain contact 122 in the recesses formed by etching the first portion of the IMD layer 118. A planarization tool may then be used to perform a planarization or polishing operation (e.g., a CMP operation) to planarize the dielectric material of the first portion of the IMD layer 118 such that the top surface of the first portion of the IMD layer 118 is approximately co-planar with the top of the gate contacts 120, and the source/drain contact 122.

As shown in FIG. 6C, in some implementations, a second portion of the IMD layer 118 is deposited on the first portion of the IMD layer 118. The second portion of the IMD layer 118 is deposited on the gate contacts 120 and on the source/drain contact 122. A deposition tool may be used to deposit dielectric material of the second portion of the IMD layer 118 using a PVD technique, an ALD technique, a CVD technique, an oxidation technique, and/or another suitable deposition technique. Based on a pattern in a mask layer, an etch tool may be used to etch portions of the second portion of the IMD layer 118 to form recesses 604 where first metallization structures 124 and 502 are to be formed. In locations where the recesses correspond to gate contacts 120 and the source/drain contact 122, the recesses 604 expose top surfaces of the gate contacts 120 and of the source/drain contact 122. A recess 606 is formed through the IMD layer 118, the dielectric layer 116, the second heterojunction layer 106, the first heterojunction layer 104, and part of the substrate 102 where the interconnect structure 504 is to be formed. In some implementations, the etch operation to etch portions of the IMD layer 118, the dielectric layer 116, the second heterojunction layer 106, the first heterojunction layer 104, and the substrate 102 to form the recesses 604 and 606 includes a dry etch operation (e.g., a plasma-based etch operation, a gas-based etch operation), a wet chemical etch operation, and/or another type of etch operation.

As shown in FIG. 6D, using a spin-coating technique, a CVD technique, a PVD technique, an ALD technique, and/or another deposition technique, a deposition tool may form first metallization structures 124 and 502 by depositing conductive material of the first metallization structures 124 and 502 in the recesses 604 formed by etching the IMD layer 118. Using a conformal deposition technique, (e.g., a CVD technique, an ALD technique, and/or another deposition technique), the interconnect structure 504 is formed in the recess 606. A deposition tool may form the interconnect structure 504 by depositing conductive material of the interconnect structure 504 in the recess 606 formed by etching the IMD layer 118, the dielectric layer 116, the second heterojunction layer 106, the first heterojunction layer 104, and part of the substrate 102. The interconnect structure 504 lines side surfaces and a bottom surface of the recess 606, and is connected to the first metallization structure 502. In some implementations, the interconnect structure 504 and first metallization structure 502 are deposited at a same time, and include the same material(s).

As shown in FIG. 6E, following the deposition of the interconnect structure 504, the dielectric fill layer 506 is deposited in the recess 606 on the interconnect structure 504 to fill in a remaining portion of the recess 606. The dielectric fill layer 506 may include the same material as the IMD layer 118, and may be deposited at the same time as a third portion of the IMD layer 118 by a deposition tool using a PVD technique, an ALD technique, a CVD technique, an oxidation technique, and/or another suitable deposition technique. Remaining conductive structures including second metallization structures 126 and 508, and interconnect structures 128 and 510, are formed using the same or similar techniques as those used for forming the gate electrodes 112, source/drain electrode 114, gate contacts 120, source/drain contact 122, and first metallization structures 124 and 502.

Subsequent backside processing to form the source/drain electrodes 130, conductive layer 134 and ground plate 136 is the same or similar to that described in connection with FIGS. 2D-2H and/or FIGS. 4E-4I.

As indicated above, FIGS. 6A-6E are provided as an example. Other examples may differ from what is described with regard to FIGS. 6A-6E.

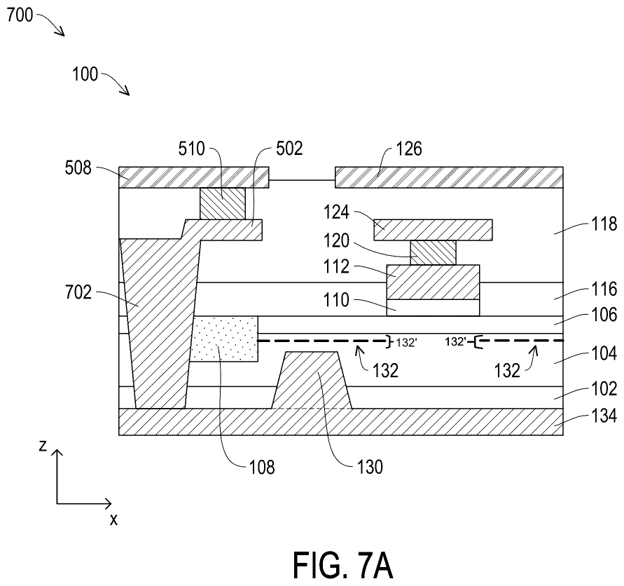

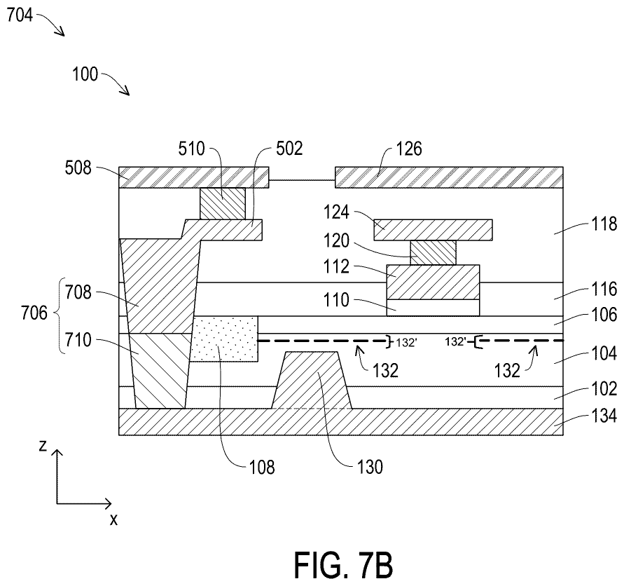

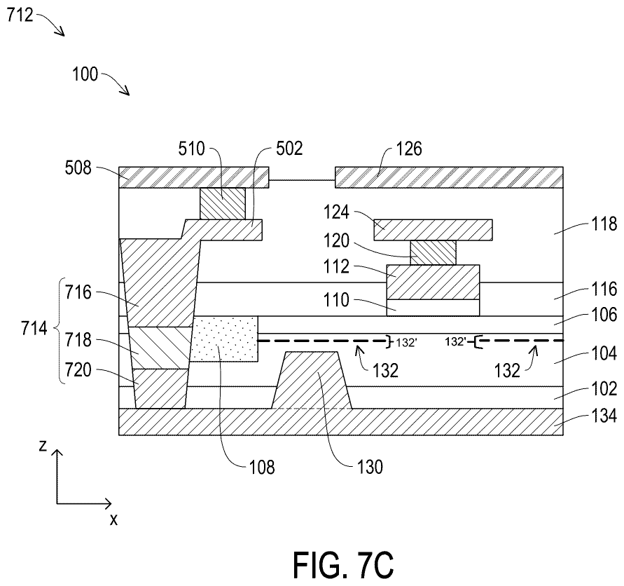

FIGS. 7A-7C illustrate example implementations 700, 704, and 712 of the semiconductor device 100 which are similar to the example implementation 500 of the semiconductor device 100. For example, although some of the components may not be shown in FIGS. 7A-7C, similar to the example implementation 500 in FIG. 5, the example implementations 700, 704, and 712 may each include components 102-140, 502, 508 and 510. In the example implementations 700, 704, and 712, the interconnect structures vary from the interconnect structure 504 in the example implementation 500.

For example, as shown in FIG. 7A, in the example implementation 700, the interconnect structure 702 includes a single conductive material and does not include a dielectric fill layer. For example, the recess in which the conductive material of the interconnect structure 702 is deposited (e.g., recess 606) is entirely filled with conductive material. In some implementations, the conductive material is the same as that of the first metallization structure 502. The interconnect structure 702 is disposed through the IMD layer 118, the dielectric layer 116, the second heterojunction layer 106, the first heterojunction layer 104, and part of the substrate 102, and lands on the conductive layer 134. The interconnect structure 702 is connected between the first metallization structure 502 and the conductive layer 134. The interconnect structure 702 is in direct contact with the first metallization structure 502, which may receive a voltage and/or signal from the second metallization structure 508 through the interconnect structure 510, and transmit the voltage and/or signal to the conductive layer 134 and/or source/drain electrodes 130.

As shown in FIG. 7B, in the example implementation 704, the interconnect structure 706 includes a first conductive material portion 708 and a second conductive material portion 710. The interconnect structure 706 does not include a dielectric fill layer. For example, the recess in which the conductive material of the interconnect structure 706 is deposited (e.g., recess 606) is filled with a first conductive material (e.g., first conductive material portion 708) and a second conductive material (e.g., second conductive material portion 710) different from the first conductive material. In some implementations, the first conductive material is the same as that of the first metallization structure 502. In some implementations, the second conductive material is the same as that of the gate contacts 120 and/or source/drain contacts 122.

The interconnect structure 706 is disposed through the IMD layer 118, the dielectric layer 116, the second heterojunction layer 106, the first heterojunction layer 104, and part of the substrate 102, and lands on the conductive layer 134. The interconnect structure 706 is connected between the first metallization structure 502 and the conductive layer 134. The interconnect structure 706 is in direct contact with the first metallization structure 502, which may receive a voltage and/or signal from the second metallization structure 508 through the interconnect structure 510, and transmit the voltage and/or signal to the conductive layer 134 and/or source/drain electrodes 130.

As shown in FIG. 7C, in the example implementation 712, the interconnect structure 714 includes a first conductive material portion 716, a second conductive material portion 718, and a third conductive material portion 720. The interconnect structure 714 does not include a dielectric fill layer. For example, the recess in which the conductive material of the interconnect structure 714 is deposited (e.g., recess 606) is filled with a first conductive material (e.g., first conductive material portion 716), a second conductive material (e.g., second conductive material portion 718) different from the first conductive material, and a third conductive material (e.g., third conductive material portion 720) different from the first conductive material, and from the second conductive material. In some implementations, the first conductive material is the same as that of the first metallization structure 502. In some implementations, the second conductive material is the same as that of the gate contacts 120 and/or source/drain contacts 122. In some implementations, the third conductive material is the same as that of the gate electrodes 112.

The interconnect structure 714 is disposed through the IMD layer 118, the dielectric layer 116, the second heterojunction layer 106, the first heterojunction layer 104, and part of the substrate 102, and lands on the conductive layer 134. The interconnect structure 714 is connected between the first metallization structure 502 and the conductive layer 134. The interconnect structure 714 is in direct contact with the first metallization structure 502, which may receive a voltage and/or signal from the second metallization structure 508 through the interconnect structure 510, and transmit the voltage and/or signal to the conductive layer 134 and/or source/drain electrodes 130.

As indicated above, FIGS. 7A-7C are provided as an example. Other examples may differ from what is described with regard to FIGS. 7A-7C.

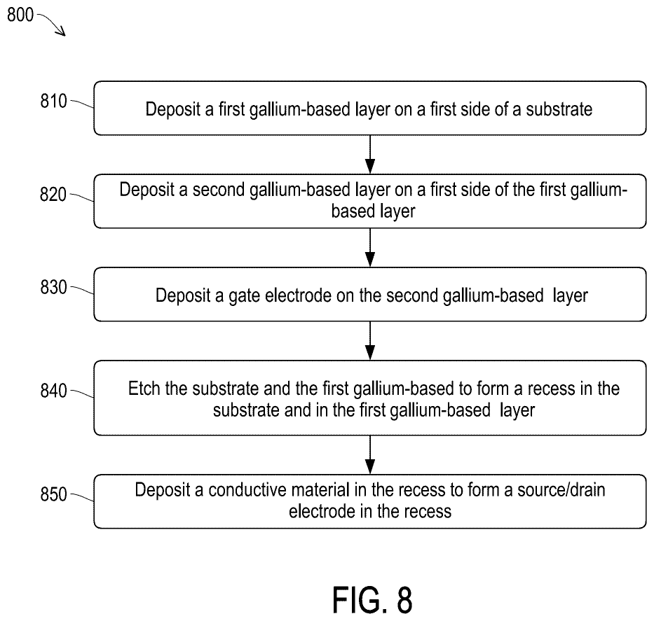

FIG. 8 is a flowchart of an example process 800 associated with forming a semiconductor device. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include depositing a first gallium-based layer on a first side of a substrate (block 810). For example, one or more semiconductor processing tools may be used to deposit a first gallium-based layer (e.g., first heterojunction layer 104) on a first side of a substrate (e.g., substrate 102), as described herein.

As further shown in FIG. 8, process 800 may include depositing a second gallium-based layer on a first side of the first gallium-based layer (block 820). For example, one or more semiconductor processing tools may be used to deposit a second gallium-based layer (e.g., second heterojunction layer 106) on a first side of the first gallium-based layer, as described herein.

As further shown in FIG. 8, process 800 may include depositing a gate electrode on the second gallium-based layer (block 830). For example, one or more semiconductor processing tools may be used to deposit a gate electrode (e.g., gate electrode 112) on the second gallium-based layer, as described herein.

As further shown in FIG. 8, process 800 may include etching the substrate and the first gallium-based layer to form a recess in the substrate and in the first gallium-based layer (block 840). For example, one or more semiconductor processing tools may be used to etch the substrate and the first gallium-based layer to form a recess (e.g., recess 206, 412) in the substrate and in the first gallium-based layer, as described herein. In some implementations, the etching is performed from a second side of the substrate opposite the first side of the substrate, and from a second side of the first gallium-based layer opposite the first side of the first gallium-based layer.

As further shown in FIG. 8, process 800 may include depositing a conductive material in the recess to form a source/drain electrode in the recess (block 850). For example, one or more semiconductor processing tools may be used to deposit a conductive material in the recess to form a source/drain electrode in the recess, as described herein.

Process 800 may include additional implementations, such as any single implementation or any combination of implementations described below and/or in connection with one or more other processes described elsewhere herein.

In a first implementation, process 800 includes depositing a seed layer before depositing the conductive material in the recess.

In a second implementation, alone or in combination with the first implementation, the seed layer includes at least one of titanium (Ti), aluminum (Al), nickel (Ni), titanium nitride (TiN), tungsten (W), tantalum (Ta), or gold (Au).

In a third implementation, alone or in combination with one or more of the first and second implementations, the first gallium-based layer includes gallium nitride (GaN).

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a semiconductor transistor device includes gate electrodes on a first side (e.g., frontside) of the device and some source/drain electrodes disposed in recesses formed from a second side (e.g., backside) of the device. The recesses are formed from the backside of the device through a substrate and into a gallium-based layer (e.g., a gallium nitride (GaN) layer). The recesses are filled with conductive (e.g., metal) material to form the source/drain electrodes. The source/drain electrodes may be formed in part of the gallium-based layer. The source/drain electrodes may be connected to a backside ground plate formed under the substrate. The ground plate may provide a connection to ground for the source/drain electrodes and may also dissipate heat. A voltage connection to the source/drain electrodes may be made by a through-gallium-via (TGV) from a voltage source on a frontside of the semiconductor device. Transistor devices with backside source/drain electrodes may reduce the width of the transistor devices since source/drain electrodes formed on opposite sides from gate electrodes may be formed at reduced lateral distances from the gate electrodes in comparison to source/drain electrodes formed on a same side as the gate electrodes. The reduced width may reduce voltage drop and heat generation. In addition, backside ground plates may be used to dissipate heat, leading to increased electron-mobility and lower serial resistance, which may increase device reliability and performance.

As described in greater detail above, some implementations described herein provide a semiconductor device. The semiconductor device includes a substrate. The semiconductor device includes a gallium-based layer on the substrate, a lattice mismatch layer in the gallium-based layer, where the lattice mismatch layer is adjacent to a first side of the gallium-based layer, and where the substrate is on a second side of the gallium-based layer opposite the first side a gate electrode of a transistor on the first side of the gallium-based layer a source/drain electrode disposed through the substrate, and through the second side of the gallium-based layer into a portion of the gallium-based layer.

As described in greater detail above, some implementations described herein provide a semiconductor device. The semiconductor device includes a buffer layer on a substrate. The semiconductor device includes a barrier layer on the buffer layer. The semiconductor device includes a gate electrode over the barrier layer. The semiconductor device includes a first source/drain electrode disposed in a portion of the barrier layer and over the buffer layer. The semiconductor device includes a second source/drain electrode disposed in a portion of the buffer layer and under the barrier layer, where the second source/drain electrode is spaced apart from the barrier layer.

As described in greater detail above, some implementations described herein provide a method. The method includes depositing a first gallium-based layer on a first side of a substrate. The method includes depositing a second gallium-based layer on a first side of the first gallium-based layer. The method includes depositing a gate electrode on the second gallium-based layer. The method includes etching the substrate and the first gallium-based layer to form a recess in the substrate and in the first gallium-based layer, where the etching is performed from a second side of the substrate opposite the first side of the substrate, and from a second side of the first gallium-based layer opposite the first side of the first gallium-based layer. The method includes depositing a conductive material in the recess to form a source/drain electrode in the recess.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gallium-based layer on the substrate;
a lattice mismatch layer in the gallium-based layer,
wherein the lattice mismatch layer is adjacent to a first side of the gallium-based layer, and
wherein the substrate is on a second side of the gallium-based layer opposite the first side;
a gate electrode of a transistor on the first side of the gallium-based layer; and
a source/drain electrode disposed through the substrate, and through the second side of the gallium-based layer into a portion of the gallium-based layer.

2. The semiconductor device of claim 1, wherein the lattice mismatch layer is over the source/drain electrode.

3. The semiconductor device of claim 1, wherein a part of the gallium-based layer is disposed between an edge of the source/drain electrode and the lattice mismatch layer.

4. The semiconductor device of claim 1, further comprising an isolation region formed in the gallium-based layer.

5. The semiconductor device of claim 1, further comprising a conductive plate disposed under the substrate,
wherein the source/drain electrode is electrically connected to the conductive plate, and
wherein the conductive plate is electrically connected to a ground voltage.

6. The semiconductor device of claim 1, further comprising:
an interconnect structure disposed through the gallium-based layer and the substrate,
wherein the interconnect structure electrically connects a first conductive layer on the first side of the gallium-based layer to a second conductive layer on the second side of the gallium-based layer, and
wherein the second conductive layer is connected to the source/drain electrode.

7. The semiconductor device of claim 6, wherein the second conductive layer is disposed under the substrate, and under the source/drain electrode.

8. The semiconductor device of claim 6, wherein a first portion of the interconnect structure disposed over the gallium-based layer comprises a first conductive material, and
wherein a second portion of the interconnect structure disposed in the gallium-based layer comprises a second conductive material.

9. The semiconductor device of claim 8, wherein a third portion of the interconnect structure disposed in the substrate comprises a third conductive material.

10. The semiconductor device of claim 6, wherein a first portion of the interconnect structure comprises a conductive material, and
wherein a second portion of the interconnect structure comprises a dielectric material.

11. A semiconductor device, comprising:
a buffer layer on a substrate;
a barrier layer on the buffer layer;
a gate electrode over the barrier layer;
a first source/drain electrode disposed in a portion of the barrier layer and over the buffer layer; and
a second source/drain electrode disposed in a portion of the buffer layer and under the barrier layer,
wherein the second source/drain electrode is spaced apart from the barrier layer.

12. The semiconductor device of claim 11, wherein the first source/drain electrode is spaced apart from the buffer layer.

13. The semiconductor device of claim 11, wherein the second source/drain electrode is disposed through the substrate.

14. The semiconductor device of claim 11, wherein a lateral dimension between an edge of the gate electrode and an edge of the second source/drain electrode is included in a range of approximately 1 micron to approximately 5 microns.

15. The semiconductor device of claim 11, further comprising a misfit dislocation region in a space between the second source/drain electrode and the barrier layer,
wherein the misfit dislocation region is in the buffer layer.

16. The semiconductor device of claim 11, further comprising further comprising a through-gallium via disposed through the buffer layer and barrier layer,
wherein the through-gallium via electrically connects a first conductive layer on a first side of the barrier layer to the second source/drain electrode on a second side of the barrier layer.

17. A method, comprising:
depositing a first gallium-based layer on a first side of a substrate;
depositing a second gallium-based layer on a first side of the first gallium-based layer;
depositing a gate electrode on the second gallium-based layer;
etching the substrate and the first gallium-based layer to form a recess in the substrate and in the first gallium-based layer,
wherein the etching is performed from a second side of the substrate opposite the first side of the substrate, and from a second side of the first gallium-based layer opposite the first side of the first gallium-based layer; and
depositing a conductive material in the recess to form a source/drain electrode in the recess.

18. The method of claim 17, further comprising depositing a seed layer before depositing the conductive material in the recess.

19. The method of claim 18, wherein the seed layer comprises at least one of titanium (Ti), aluminum (Al), nickel (Ni), titanium nitride (TiN), tungsten (W), tantalum (Ta), or gold (Au).

20. The method of claim 17, wherein the first gallium-based layer comprises gallium nitride (GaN).
